(19) United States
(12) Patent Application Publication
(10) Pub. No.: US 2025/0344378 A1
(43) Pub. Date: Nov. 6, 2025

(54) SEMICONDUCTOR MEMORY DEVICE AND MANUFACTURING METHOD THEREOF

(71) Applicant: Samsung Electronics Co., Ltd., Suwon-si (KR)

(72) Inventor: Masayuki TERAI, Suwon-si (KR)

(73) Assignee: Samsung Electronics Co., Ltd., Suwon-si (KR)

(21) Appl. No.: 19/032,575

(22) Filed: Jan. 21, 2025

(30) Foreign Application Priority Data
May 3, 2024 (KR) 10-2024-0059232

(51) Int. Cl. H10B 12/00

(52) U.S. Cl. CPC H10B 12/488; H10B 12/03; H10B 12/315; H10B 12/482

(57) ABSTRACT

Provided is a semiconductor memory device that includes mold insulation films extending along a first direction, a channel pattern protruding from the mold insulation films in a second direction, a gate insulation film covering at least a portion of the mold insulation films and the channel pattern, a word line on the gate insulation film, and a gate capping film covering at least a portion of the gate insulation film and the word line, wherein the gate capping film includes a first part that overlaps the word line in the second direction in a cross-sectional view cut along the first direction, and a second part below the first part, and a width of the second part is greater than a width of the first part based on the second direction, the gate insulation film has a first width and a second width substantially the same.

### CROSS-REFERENCE TO RELATED APPLICATION(S)

This application claims the benefit of Korean Patent Application No. 10-2024-0059232, filed on May 3, 2024, in the Korean Intellectual Property Office, the disclosure of which is incorporated herein by reference.

### BACKGROUND

### 1. Field of the Invention

Example embodiments relate to a semiconductor memory device and a method of manufacturing the same.

### 2. Description of the Related Art

Manufacturing technology for semiconductor memory devices is being developed to improve the integration, operation speed, and yield of semiconductor memory devices. A vertical channel transistor (VCT) is proposed for high integration of semiconductor memory devices.

### SUMMARY

An aspect provides a semiconductor memory device with improved integration and electrical characteristics.

Another aspect also provides a method of manufacturing the semiconductor memory device with improved integration and electrical characteristics.

The technical tasks to be achieved by the present example embodiments are not limited to the technical tasks described above, and other technical tasks may be inferred from the following example embodiments by those skilled in the art.

According to an aspect, there is provided a semiconductor memory device that includes mold insulation films extending along a first direction and spaced apart from each other based on a second direction intersecting the first direction; a channel pattern protruding from the mold insulation films in the second direction; a gate insulation film covering at least a portion of the mold insulation films and the channel pattern; a word line on the gate insulation film such that the gate insulation film separates the word line from the channel pattern and a respective one of the mold insulation films; and a gate capping film extending along the first direction and covering at least a portion of the gate insulation film and the word line, wherein the gate capping film includes a first part overlapping the word line in the second direction in a cross-sectional view cut along the first direction, and a second part below the first part in a vertical direction that intersects the first direction and the second direction, wherein, a width of the second part in the second direction is greater than a width of the first part in the second direction, wherein the gate insulation film has a first width between the channel pattern and the word line based on the first direction and a second width between the channel pattern and the word line based on the second direction, and wherein the first width and the second width are substantially the same.

According to another aspect, there is provided a method of manufacturing a semiconductor memory device, the method includes forming data stored patterns (DSPs) in a grid shape such that the DSPs are each spaced part at a first predetermined interval in a first direction and a second direction intersecting with the first direction; forming mold insulation films extending along the first direction and spaced apart from each other based on the second direction and placed between the DSPs; forming a first pre-channel pattern covering the mold insulation films; forming a second pre-channel pattern by removing a portion of the first pre-channel pattern such that a portion of a side of the mold insulation films extending along the first direction is exposed; forming channel alignment films on the exposed side of the mold insulation films such that the channel alignment films are in a grid shape and spaced apart from each other at a second predetermined interval in the first direction and the second direction; forming a channel pattern on top of the channel alignment films by patterning the second pre-channel pattern using the channel alignment films; forming a gate insulation film such that the gate insulation films covers the mold insulation films, the channel pattern and the channel alignment films; and forming a word line on the gate insulation film such that the word line extends along the first direction between the channel pattern.

According to another aspect, there is provided a semiconductor memory device that includes mold insulation films extending along a first direction and spaced apart from each other based on a second direction intersecting a first direction; a channel pattern protruding from the mold insulation films in a second direction; a gate insulation film covering at least a portion of the mold insulation films and the channel pattern; a word line on the gate insulation film such that the gate insulation film separates the word line from the channel pattern and a respective one of the mold insulation films; a gate capping film extending along the first direction and covering at least a portion of the gate insulation film and the word line; a bit line at a bottom of the mold insulation films and extending in the second direction based on a vertical direction that intersects the first direction and the second direction; a connection plug connecting the bit line and the channel pattern; and data stored patterns (DSPs) on top of the channel pattern and the gate insulation film, wherein the gate capping film includes a first part overlapping the word line in the second direction in a cross-sectional view cut along the first direction, and a second part closer to an upper surface of the bit line than the first part in the vertical direction, wherein a width of the second part in the second direction is greater than a width of the first part in the second direction, wherein the gate insulation film has a first width between the channel pattern and the word line in the first direction and a second width between the channel pattern and the word line in the second direction, and the first width and the second width are substantially the same, and wherein an upper surface of the mold insulation films, an upper surface of the channel pattern and an upper surface of the gate insulation film are on an same plane, the gate capping film is between a bottom surface of the channel pattern and the upper surface of the bit line, and the connection plug has an upper surface that is above a bottom surface of the mold insulation films.

Additional aspects of example embodiments will be set forth in part in the description which follows and, in part, will be apparent from the description, or may be learned by practice of the disclosure.

According to example embodiments, a semiconductor memory device is provided, with improved integration and electrical characteristics, and a method of manufacturing the semiconductor memory device.

Additional features and advantages of the invention concepts will be set forth in the description which follows, and in part will be apparent from the description, or may be learned by practice of the invention. The objectives and other advantages of the invention will be realized and attained by the structure particularly pointed out in the written description and claims hereof as well as the appended drawings.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a plan view illustrating a semiconductor memory device according to a first example embodiment;

FIG. 2 is a cross-sectional view taken along A-A′ of FIG. 1;

FIG. 3 is a plan view illustrating a semiconductor memory device according to a second example embodiment;

FIG. 4 is a cross-sectional view taken along B-B′ in FIG. 3; and

FIGS. 5 to 48 are diagrams for explaining a method of manufacturing a semiconductor memory device according to some example embodiments.

### DETAILED DESCRIPTION

Prior to the detailed description of the present disclosure, terms or words used in the specification and claims may not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are only the most preferred embodiments of the present disclosure, and do not necessarily represent the entire technical idea of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different embodiments may be described using the same reference numerals or symbols. In other words, even if a component or an element having the same reference numeral is shown in multiple drawings, the multiple drawings may not all represent one example embodiment. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry terms. Additionally, whenever a range of values is enumerated, the range includes all values within the range as if recorded explicitly clearly, and may further include the boundaries of the range. Accordingly, the range of “X” to “Y” includes all values between X and Y, including X and Y.

In the present disclosure, when an element is described as being “on” or “adjacent to” another element, the element may be understood as being in direct contact with or connected to the another element, but it also may be understood that another element exist between the two.

Further, in the present disclosure, when an element is described as being “on top of” another element, it may be understood as existing above in the vertical direction, unless otherwise defined, as being above the in +D3 direction in the drawing, and the two elements may be in direct contact or connected, but it may also be understood that another element exists between the two. Further, in the present disclosure, when an element is described as being “underneath” another element, it may be understood as existing below based on the vertical direction, unless otherwise defined, being further below based on the −D3 direction in the drawing, and the two elements may be in direct contact or connected, but it may also be understood that another element exists between the two.

Further, in the present disclosure, when an element is described as being “directly on,” “adjacent to” or “in contact with” another element, it may be understood that there is no other element between the two. Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as an upper side, top, a lower side, bottom, a side, front and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

Further, hereinafter, “US” indicated in reference numerals refers to an upper surface, and “BS” indicated in reference numerals refers to a bottom surface.

The drawings illustrated in the present disclosure are according to mere example embodiments, and the ratio of the width, the length and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the +direction, and the direction opposite to the direction indicated by the arrow (rotated by 180 degrees) may be the −direction.

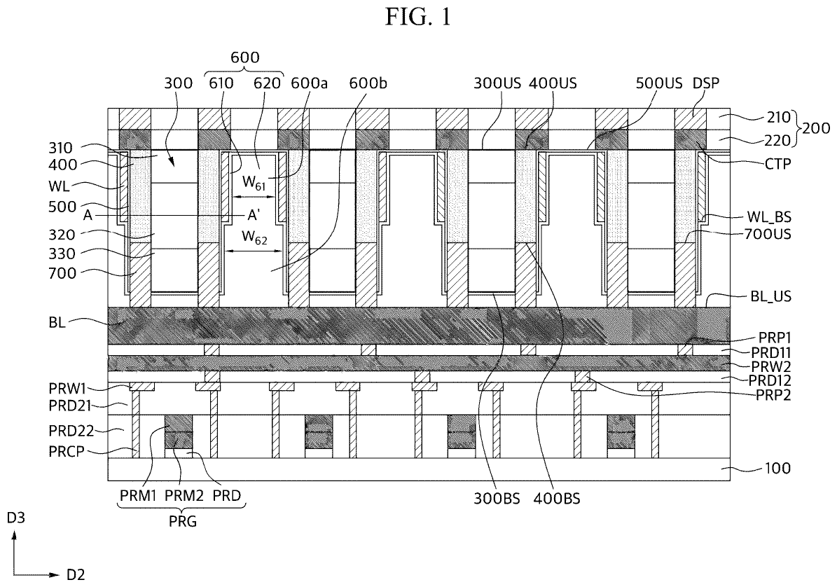

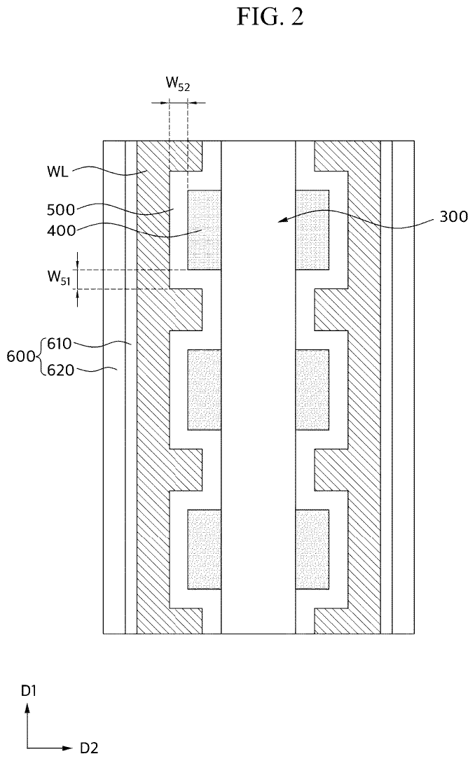

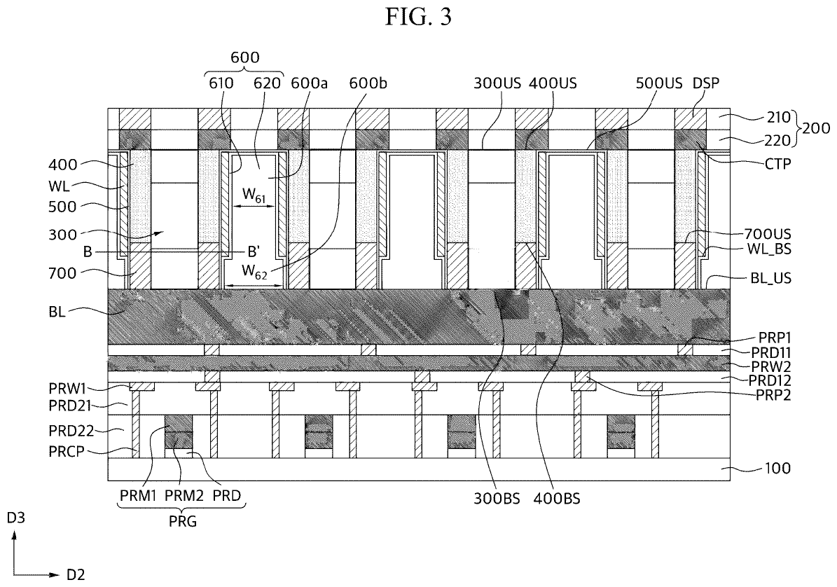

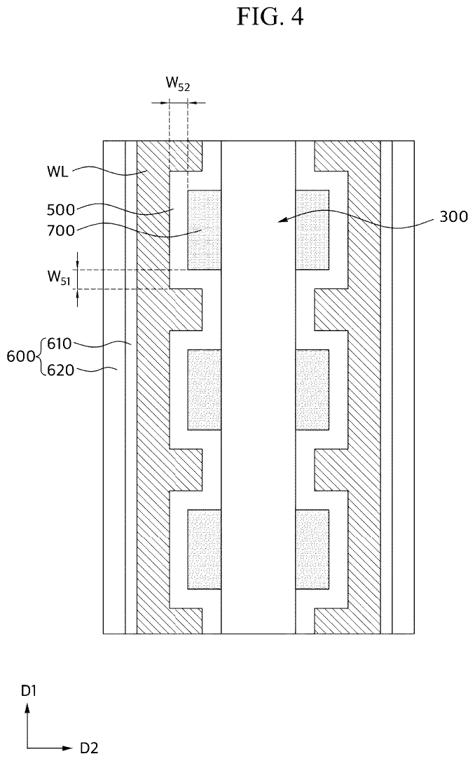

FIG. 1 is a plan view illustrating a semiconductor memory device 10 according to a first example embodiment. FIG. 2 is a cross-sectional view taken along AA′ of FIG. 1. FIG. 3 is a plan view illustrating the semiconductor memory device 10 according to a second example embodiment. FIG. 4 is a cross-sectional view taken along B-B′in FIG. 3.

According to the example embodiments, the semiconductor memory device 10 may include a memory cell including a VCT.

According to the example embodiments, the semiconductor memory device 10 may include a substrate 100, a peripheral gate structure (PRG), an insulation layer 200, a data stored pattern (DSP), and a contact pattern (CTP).

According to some example embodiments, the substrate 100 may be a semiconductor substrate. For example, the substrate 100 may further include one or more of silicon, a silicon germanium compound, an indium antimonide compound, a lead tellurium compound, an indium arsenide compound, an indium compound, an gallium arsenide compound, gallium antimonide compound, and/or the like. However, the substrate 100 is not limited thereto.

According to some example embodiments, a peripheral gate structure PRG may be disposed on the substrate 100. The peripheral gate structure PRG may include a peripheral gate insulation film PRD, a peripheral bottom part conductive pattern PRM2, and a peripheral upper part conductive pattern PRM1. The substrate 100 may include a cell array area and peripheral circuitry area. The peripheral gate structure PRG may be placed throughout the cell array area and the peripheral circuitry area. In other words, a portion of the peripheral gate structure PRG may be placed in the cell array area of the substrate 100, and the other portion of the peripheral gate structure PRG may be placed in the peripheral circuitry area of the substrate 100.

According to some example embodiments, the peripheral gate structure PRG may be included in sensing transistors, transfer transistors, driving transistors, and/or the like. The type of transistor placed in the cell array area and the peripheral circuitry area of the substrate 100 may vary depending on the design arrangement of the semiconductor memory device 10.

According to some example embodiments, the peripheral gate insulation film PRD may contain an insulating material. The insulating material may include, for example, a silicon oxide film, a silicon oxynitride film, a high dielectric constant insulating film having a higher dielectric constant than the silicon oxide film, a combination thereof, and/or the like. The high dielectric constant insulating film may include an insulating material of, for example, one or more selected of metal oxide, metal oxynitride, metal silicon oxide, metal silicon oxynitride, and/or the like. However, the high dielectric constant insulating film is not limited thereto.

Further, in the present disclosure, unless described otherwise, the insulating material may include one or more of a silicon oxide film, a silicon oxynitride film, a high dielectric constant insulating film with a higher dielectric constant than the silicon oxide film, and/or the like.

According to some example embodiments, the peripheral bottom part conductive pattern PRM2 and the peripheral upper part conductive pattern PRM1 may each include a conductive material. In the present disclosure, unless otherwise limited, the conductive material may include one or more doped semiconductor materials, conductive metal nitrides, conductive metal silicon nitrides, metal carbonitrides, conductive metal silicides, conductive metal oxides, a 2D material, metals and metal alloys. For example, each of the peripheral bottom part conductive pattern PRM2 and the peripheral upper part conductive pattern PRM1 may include one or more of a doped semiconductor material, a conductive metal nitride, a conductive metal silicon nitride, a metal carbonitride, a conductive metal silicide, a conductive metal oxide, a two-dimensional (2D) material, a metal or metal alloy, and/or the like. The peripheral gate structure PRG is illustrated as including a plurality of conductive patterns, but is not limited thereto.

In some example embodiments, the 2D material of the semiconductor memory device 10 may be a metallically conductive material and/or a semiconductor material. The 2D material may include a 2D allotrope or a 2D compound. For example, the 2D material may include one or more of graphene, molybdenum disulfide (MoS₂), molybdenum diselenide (MoSe₂), tungsten diselenide (WSe₂), and tungsten disulfide (WS₂). However, the 2D material is not limited thereto. In other words, since the above-described 2D materials are listed only as examples, 2D materials that can be included in the semiconductor memory device 10 of the present disclosure are not limited by the above-described materials.

According to some example embodiments, the semiconductor memory device 10 may include a first peripheral bottom part insulation film PRD21 and a second peripheral bottom part insulation film PRD22. The first peripheral bottom part insulation film PRD21 and the second peripheral bottom part insulation film PRD22 may be disposed on the substrate 100 in order to be laminated in the order of the second peripheral bottom part insulation film PRD22 and the first peripheral bottom part insulation film PRD21 on the substrate 100. The first peripheral bottom part insulation film PRD21 and the second peripheral bottom part insulation film PRD22 may each independently include an insulating material. The insulating material included in the first peripheral bottom part insulation film PRD21 and the second peripheral bottom part insulation film PRD22 may be the same and/or different from each other.

According to some example embodiments, the semiconductor memory device 10 may include a first peripheral wiring line PRW1 and a peripheral contact plug PRCP. The first peripheral wiring line PRW1 and the peripheral contact plug PRCP may be placed within the first peripheral bottom part insulation film PRD21 and the second peripheral bottom part insulation film PRD22. It is illustrated that the first peripheral wiring line PRW1 and the peripheral contact plug PRCP are different films, but the present disclosure is not limited thereto. The boundary between the first peripheral wiring line PRW1 and the peripheral contact plug PRCP may be indistinguishable. The first peripheral wiring line PRW1 and the peripheral contact plug PRCP may each independently contain a conductive material.

According to some example embodiments, the semiconductor memory device 10 may include a first peripheral upper part insulation film PRD11 and a second peripheral upper part insulation film PRD12. The first peripheral upper part insulation film PRD11 and the second peripheral upper part insulation film PRD12 may be placed on top of the first peripheral bottom part insulation film PRD21. The first peripheral upper part insulation film PRD11 may be placed on the second peripheral upper part insulation film PRD12. The first peripheral upper part insulation film PRD11 and the second peripheral upper part insulation film PRD12 may each independently include an insulating material. The insulating material included in the first peripheral upper part insulation film PRD11 and the second peripheral upper part insulation film PRD12 may be same and/or different from each other.

According to some example embodiments, the semiconductor memory device 10 may include a second peripheral wiring line PRW2, a first peripheral connection plug PRP1, and a second peripheral connection plug PRP2. The second peripheral wiring line PRW2 may be placed between the first peripheral upper part insulation film PRD11 and the second peripheral upper part insulation film PRD12. The second peripheral connection plug PRP2 may be placed within the second peripheral upper part insulation film PRD12, and may be electrically connected to the second peripheral wiring line PRW2. The boundary between the second peripheral wiring line PRW2 and the second peripheral connection plug PRP2 may not be distinguished.

Meanwhile, according to some example embodiments, the first peripheral upper part insulation film PRD11 may be placed on the second peripheral wiring line PRW2, and may be single-layered, but may also be multi-layered. The first peripheral connection plug PRP1 may be placed within the first peripheral upper part insulation film PRD11. The first peripheral connection plug PRP1 may be electrically connected to the second peripheral wiring line PRW2. The boundary between the second peripheral wiring line PRW2 and the first peripheral connection plug PRP1 may not be distinguished. The second peripheral wiring line PRW2, the first peripheral connection plug PRP1, and the second peripheral connection plug PRP2 may each independently include a conductive material. The second peripheral connection plug PRP2 may be electrically connected to the first peripheral wiring line PRW1.

According to some example embodiments, the semiconductor memory device 10 may include the insulation layer 200 on top of the substrate 100. The insulation layer 200 may include an insulating material. For example, the insulation layer 200 may include one or more of oxide-based insulating materials and/or nitride-based insulating materials, but is not limited thereto. The insulation layer 200 may include a first insulation layer 210 including a DSP arranged in a grid shape and a second insulation layer 220 including a CTP connected to the DSP. It will be described in more detail later but the CTP may be connected to a channel pattern 400. The first insulation layer 210 and the second insulation layer 220 may be stacked, and may be arranged and stacked so that the DSP and the CTP are in contact with each other, respectively. In at least some embodiments, the first insulation layer 210 and the second insulation layer 220 may include the same insulating material.

Meanwhile, according to some example embodiments, the semiconductor memory device 10 may further include a landing pad (not illustrated) containing a conductive material on the CTP. The landing pad may be connected to the DSP, and the landing pad and the CTP may be connected to the channel pattern 400.

According to some example embodiments, the DSP may be arranged in a grid shape and spaced apart at predetermined intervals based on the first direction D1 and the second direction D2. This arrangement may be called a matrix arrangement. Since the CTP is arranged to contact each DSP at a corresponding position, the CTP may also have a matrix arrangement. In the present disclosure, the second direction D2 may indicate a direction that intersects the first direction D1, and referring to the drawings, specifically, the second direction D2 may indicate a direction perpendicular to the first direction D1.

According to some example embodiments, the DSP may include a storage electrode, a plate electrode, and a capacitor dielectric film interposed between the storage electrode and the plate electrode. In this case, the storage electrode may be in contact with the CTP. From a planar perspective, the storage electrode may have various shapes, such as circular, oval, rectangular, square, diamond, or hexagonal shapes. The DSP may completely or partially overlap the CTP when viewed in the third direction (or in a plan view). Further, one side of the DSP may be in full or partial contact with one side of the CTP. In the present disclosure, the third direction D3 (or the vertical direction) may indicate a direction that intersects the first direction D1 and the second direction D2. Specifically, referring to the drawings, the third direction D3 may indicate a direction perpendicular to the first direction D1 and the second direction D2.

According to some example embodiments, based on the third direction D3, the DSP may be placed on top of the channel pattern 400 and a gate insulation film 500 which will be described later. The DSP may be placed on an upper surface 400US of the channel pattern and an upper surface 500US of the gate insulation film based on the third direction D3.

According to some example embodiments, the DSP may be a variable resistance pattern that can be switched between two resistance states by electrical pulses applied to the memory element. For example, the DSP may include one or more of a phase-change material whose crystal state changes depending on the amount of current, perovskite compounds, transition metal oxide, magnetic materials, ferromagnetic substances, and/or antiferromagnetic materials.

According to some example embodiments, the DSP may be a capacitor, for example. The DSP may be above the CTP based on the third direction D3.

According to some example embodiments, the semiconductor memory device 10 may include a mold insulation film 300, the channel pattern 400, the gate insulation film 500, a gate capping film 600, a connection plug 700, a word line WL, and a bit line BL.

According to some example embodiments, the semiconductor memory device 10 may include mold insulation films 300 that extend along the first direction D1 and are spaced apart from each other based on the second direction D2. The mold insulation films 300 may be placed on the insulation layer 200. Further, the mold insulation film 300 may be arranged not to overlap the DSP when viewed from the third direction D3. The mold insulation film 300 may have a multi-layer structure. The mold insulation film 300 may include an insulating material.

According to some example embodiments, the mold insulation film 300 may include a first mold insulation film 310, a second mold insulation film 320, and a third mold insulation film 330. The number of layers is not particularly limited. The first mold insulation film 310 may be in contact with the insulation layer 200. The second mold insulation film 320 may be laminated on the first mold insulation film 310. The third mold insulation film 330 may be laminated on the second mold insulation film 320. The first mold insulation film 310 and the third mold insulation film 330 at both ends based on the third direction D3 may include the same insulating material. The insulating material included in the first mold insulation film 310 and the third mold insulation film 330 may be different from the insulating material included in the second mold insulation film 320. The first mold insulation film 310 and the third mold insulation film 330 at both ends based on the third direction D3 may include an oxide-based insulating material. The second mold insulation film 320 located between the first mold insulation film 310 and the third mold insulation film 330 based on the third direction D3 may include a nitride-based insulating material. However, the insulating material is not limited thereto.

According to some example embodiments, the semiconductor memory device 10 may include the channel pattern 400 disposed to protrude from the mold insulation film 300 in the second direction D2. The channel pattern 400 may be extended in the third direction D3. The upper surface 400US of the channel pattern may be in contact with at least a portion of the CTP. The channel pattern 400 may be in non-contact with the insulation layer 200 on which the CTP is not placed.

According to some example embodiments, the channel pattern 400 may be arranged in a grid shape and spaced apart at predetermined intervals based on the first direction D1 and the second direction D2.

The channel pattern 400 may include an oxide semiconductor material. The channel pattern 400 may include, for example, semiconductive metal oxide. In some example embodiments, the channel pattern 400 may be an amorphous semiconductive metal oxide film, a polycrystalline semiconductive metal oxide film, and/or a combination of an amorphous metal oxide film and a polycrystalline metal oxide film. In another example embodiments, the channel pattern 400 may be a c-axis aligned crystalline (CAAC) metal oxide film.

According to some example embodiments, the channel pattern 400 may include, for example, one of indium (In) oxide, tin (Sn) oxide, zinc (Zn) oxide, In—Zn-based oxide (IZO), Sn—Zn-based oxide, aluminum (Al)—Zn-based oxide, Zn-magnesium (Mg)-based oxide, Sn—Mg-based oxide, In—Mg-based oxide, In-gallium (Ga)-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In-hafnium (Hf)—Zn-based oxide, In-lanthanum (La)—Zn-based oxide, In-cerium (Ce)—Zn-based oxide, In-praseodymium (Pr)—Zn-based oxide, In-neodymium (Nd)—Zn-based oxide, In-samarium (Sm)—Zn-based oxide, In-europium (Eu)—Zn-based oxide, In-gadolinium (Gd)—Zn-based oxide, In-terbium (Tb)—Zn-based oxide, In-dystrosium (Dy)—Zn-based oxide, In-holmium (Ho)—Zn-based oxide, In-erbium (Er)—Zn-based oxide, In-thulium (Tm)—Zn-based oxide, In-ytterbium (Yb)—Zn-based oxide, In-ruthenium (Ru)—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, In—Hf—Al—Zn-based oxide, and/or the like. However, the channel pattern 400 is not limited thereto.

Here, the IGZO refers to an oxide containing In, Ga, and Zn as main components, and does not refer to the ratio of In, Ga, and Zn. In other words, taking IGZO as an example, the channel pattern 400 may include IGZO, InₓGa_{y}Zn_{z}O. IGZO (In:Ga:Zn=1:1:1), which contains indium, gallium and zinc in equal proportions, may be an In—Ga—Zn-based oxide. Ga-rich IGZO may have a higher gallium ratio than IGZO (In:Ga:Zn=1:1:1) and a lower indium ratio than IGZO (In:Ga:Zn=1:1:1). Ga-rich IGZO may also be an In—Ga—Zn-based oxide. Further, In-rich IGZO may have a higher indium ratio than IGZO (In:Ga:Zn=1:1:1) and a lower gallium ratio than IGZO (In:Ga:Zn=1:1:1). In-rich IGZO may also be an In—Ga—Zn-based oxide.

The example embodiments are described with IGZO, but the present disclosure is not limited thereto. If each channel pattern 400 contains ternary or more metal oxides, the above descriptions may also be applied. Further, if the channel pattern 400 contains In—Ga—Zn oxide, the channel pattern 400 may further include doped metal elements other than In, Ga, and Zn.

According to some example embodiments, the semiconductor memory device 10 may include the gate insulation film 500 that covers at least a portion of the mold insulation film 300 and the channel pattern 400. The gate insulation film 500 may be a single layer. Based on the second direction D2, the channel pattern 400 may be placed between the gate insulation film 500 and the mold insulation film 300. The gate insulation film 500 may cover a bottom surface 300BS of the mold insulation film. The gate insulation film 500 may cover one side (the side according to the second direction) of the channel pattern 400. The gate insulation film 500 may include an insulating material. For example, the gate insulation film 500 may include a silicon oxide film, a silicon oxynitride film, a high dielectric constant insulating film having a higher dielectric constant than the silicon oxide film, or a combination thereof.

According to some example embodiments, the gate insulation film 500 may have a first width W₅₁ between the channel pattern 400 and the word line WL based on the first direction D1 and a second width W₅₂ between the channel pattern 400 and the word line WL based on the second direction D2. The first width W₅₁ and the second width W₅₂ may be the same and/or substantially similar. For example, the difference between the first width W₅₁ and the second width W₅₂ may be within 10%. Since the first width W₅₁ and the second width W₅₂ are the same and/or substantially similar, the channel pattern 400 may be protected from damage, thereby improving reliability.

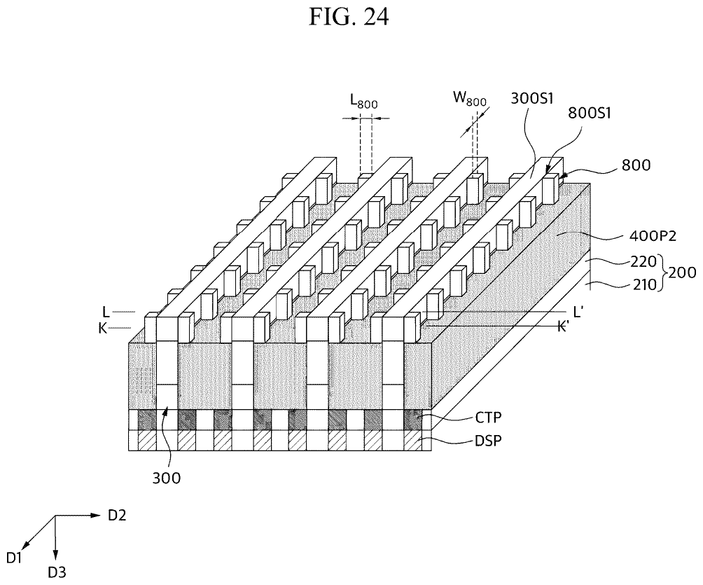

According to some example embodiments, the semiconductor memory device 10 uses a channel alignment film 800 in FIG. 24, which will be described later, to form the channel pattern 400, and through this, the gate insulation film 500 may be formed in one step, and thus the semiconductor memory device 10 may form the first width W₅₁ and the second width W₅₂ to be the same. Meanwhile, the first width W₅₁ and the second width W₅₂ may be 5 nm or less.

According to some example embodiments, in the semiconductor memory device 10, based on the third direction D3, an upper surface 300US of the mold insulation film, the upper surface 400US of the channel pattern, and the upper surface 500US of the gate insulation film may all be on the same plane.

According to some example embodiments, the semiconductor memory device 10 may include the word line WL disposed on the gate insulation film 500. When viewed from the second direction D2, as the gate insulation film 500 and at least a portion of the word line WL overlap, the word line WL may be extended according to the first direction D1. When viewed from the third direction D3, the word line WL may be placed to overlap a portion of the DSP. Further, the word line WL may be arranged to face the CTP with the gate insulation film 500 in between based on the third direction D3. Based on the third direction D3, the upper surface of the word line WL may be adjacent to the bottom surface of the CTP compared to an upper surface BL_US of the bit line.

According to some example embodiments, the semiconductor memory device 10 may include the gate insulation film 500 and the gate capping film 600 that covers at least a portion of the word line WL. On the cross section cut along the first direction D1, the gate capping film 600 may include a first part 600a and a second part 600b excluding the first part 600a overlapping the word line WL in the first direction D1 and the second direction D2. The second part 600b may be placed at the bottom part of the first part 600a. Based on the second direction D2, the width W₆₂ of the second part 600b may be larger than the width W₆₁ of the first part 600a. The second part 600b may be placed below the first part 600a. Specifically, based on the +third direction which is +D3, the second part 600b may be placed at the bottom part of the first part 600a. On the cross section cut along the first direction D1, the second part 600b may include part A that does not overlap the word line WL in the first direction D1 and the second direction D2, but may overlap the connection plug 700 in the first direction D1 and the second direction D2. The width W₆₂ of the second part 600b may indicate the width of part A based on the second direction D2.

According to some example embodiments, the gate capping film 600 may fill the space between the mold insulation films 300 that are spaced apart from each other. The gate capping film 600 may fill the space between the word lines WL that are spaced apart from each other. Further, the gate capping film 600 may fill the space between the connection plugs 700 that are spaced apart from each other and the space between the channel pattern 400 that are spaced apart from each other. When viewed from the first direction D1, the width of the bottom surface of the gate capping film 600 located between the mold insulation films 300 may be larger than the width of the upper surface based on the second direction D2. This may be because, based on the third direction D3, the upper surface of the word line WL is placed adjacent to the bottom surface of the CTP compared to the upper surface BL_US of the bit line.

According to some example embodiments, the gate capping film 600 may include a liner film 610 in contact with the gate insulation film 500 and the word line WL, and a filling film 620 that fills the space between the mold insulation films 300.

According to some example embodiments, the semiconductor memory device 10 may be placed on the bottom surface 300BS of the mold insulation film based on the third direction D3, and may include the bit line BL extending in the second direction D2. Based on the third direction D3, a bottom surface 400BS of the channel pattern may be separated from the upper surface BL_US of the bit line. Further, based on the third direction D3, a bottom surface WL_BS of the word line may be spaced apart from the upper surface BL_US of the bit line.

Further, according to some example embodiments, on the cross section cut along the first direction D1, the gate capping film 600 may include the first part 600a and the second part 600b excluding the first part 600a overlapping the word line WL in the first direction D1 and the second direction D2. Based on the third direction D3, the second part 600b may be placed closer to the upper surface BL_US of the bit line than the first part 600a.

According to some example embodiments, the semiconductor memory device 10 may include the connection plug 700 connecting the bit line BL and the channel pattern 400. Based on the third direction D3, an upper surface 700US of the connection plug may be on the same plane as the bottom surface 400BS of the channel pattern. Based on the third direction D3, the upper surface 700US of the connection plug may be placed above the bottom surface 300BS of the mold insulation film.

Referring to FIGS. 1 and 2, in the semiconductor memory device 10, the upper surface 700US of the connection plug may be placed lower than the bottom surface WL_BS of the word line based on the third direction D3.

Referring to FIG. 1, in the semiconductor memory device 10, the bottom surface 300BS of the mold insulation film and the upper surface BL_US of the bit line may be spaced apart based on the third direction D3. The gate capping film 600 may be disposed on at least a portion between the bottom surface 300BS of the mold insulation film and the upper surface BL_US of the bit line.

According to some example embodiments, in the semiconductor memory device 10, the upper surface 700US of the connection plug may be placed on the same plane or above the bottom surface WL_BS of the word line based on the third direction D3. Referring to FIGS. 3 and 4, in the semiconductor memory device 10, the upper surface 700US of the connection plug may be placed above the bottom surface WL_BS of the word line based on the third direction D3. With the arrangement, the word line WL may be connected to the connection plug 700 with the gate insulation film 500 in between based on the second direction D2, and as resistance is lowered, integration and electrical characteristics may be improved.

Referring to FIG. 3, in the semiconductor memory device 10, the bottom surface 300BS of the mold insulation film and the upper surface BL_US of the bit line may be on the same plane based on the third direction D3.

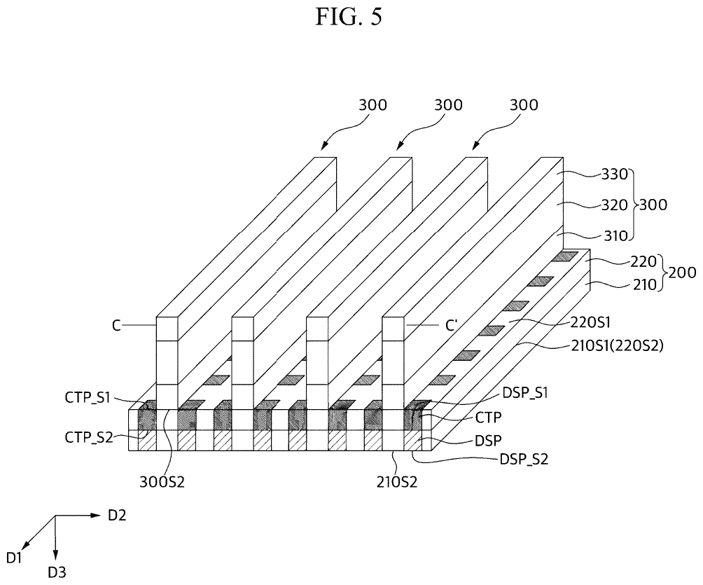

FIGS. 5 to 48 are diagrams for explaining a method of manufacturing the semiconductor memory device 10 according to some example embodiments. Below, the contents that are different from the above contents are mainly described. Reference may be made to the foregoing descriptions unless contradictory.

According to some example embodiments, in the drawings for explaining the method of manufacturing the semiconductor memory device 10, a first surface S1 of an element may correspond to a bottom surface BS in FIG. 1 or 3, and a second surface S2 of an element may correspond to an upper surface US in FIG. 1 or 3.

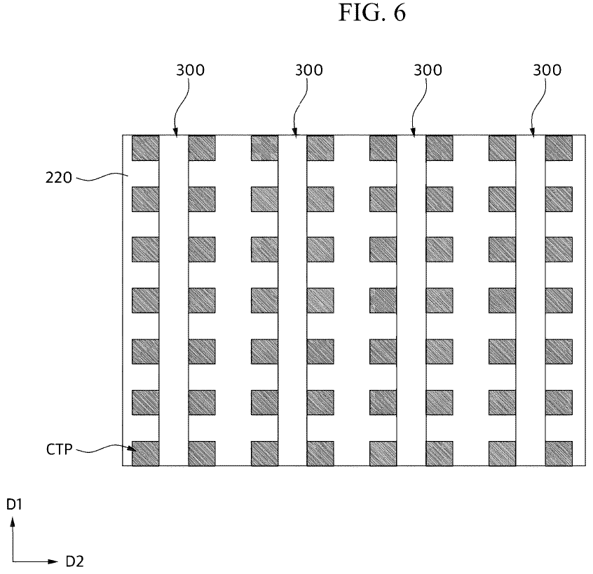

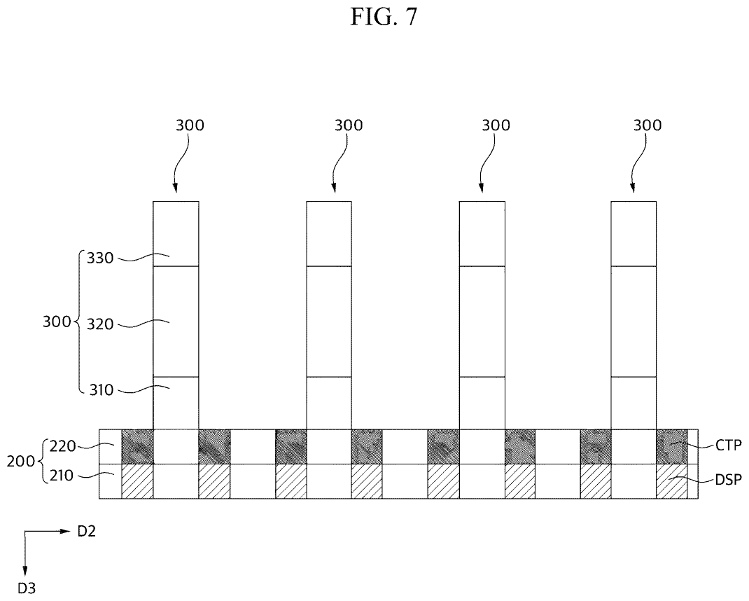

FIG. 5 is a perspective view that illustrates the mold insulation film 300 formed on the insulation layer 200 that includes the first insulation layer 210 including the DSP and the second insulation layer 220 with the CTP. FIG. 6 is a layout view of FIG. 5, and FIG. 7 is a cross-sectional view taken along C-C′ of FIG. 5.

Referring to FIGS. 5 to 7, the method of manufacturing the semiconductor memory device 10 may include forming the mold insulation films 300 extending along the first direction D1 and spaced apart from each other based on the second direction D2.

Meanwhile, FIG. 5 illustrates flipped state of the insulation layer 200. According to some example embodiments, the method of manufacturing the semiconductor memory device 10 may include forming the DSPs arranged in a grid shape spaced apart at predetermined intervals based on the first direction D1 and the second direction D2. If the channel pattern 400 is formed first and then the DSPs are formed, there is a possibility that the materials included in the channel pattern 400 may be damaged by being processed at the higher temperatures used to process the DSPs. Therefore, in the method of manufacturing the semiconductor memory device 10, forming the DSPs may be performed before forming the mold insulation film 300.

According to some example embodiments, based on the third direction D3, the DSPs may include a first surface DSP_S1 and a second surface DSP_S2, which is the opposite side to the first surface DSP_S1. As described above, the first surface DSP_S1 of the DSP may correspond to the bottom surface of the DSP in FIG. 1. The second surface DSP_S2 of the DSP may correspond to the upper surface of the DSP in FIG. 1.

According to some example embodiments, based on the third direction D3, the CTP may include a first surface CTP_S1, and a second surface CTP_S2 that is the opposite side of the first surface CTP_S1. As described above, the first surface CTP_S1 of the CTP may correspond to the bottom surface of the CTP in FIG. 1. The second surface CTP_S2 of the CTP may correspond to the upper surface of the CTP in FIG. 1.

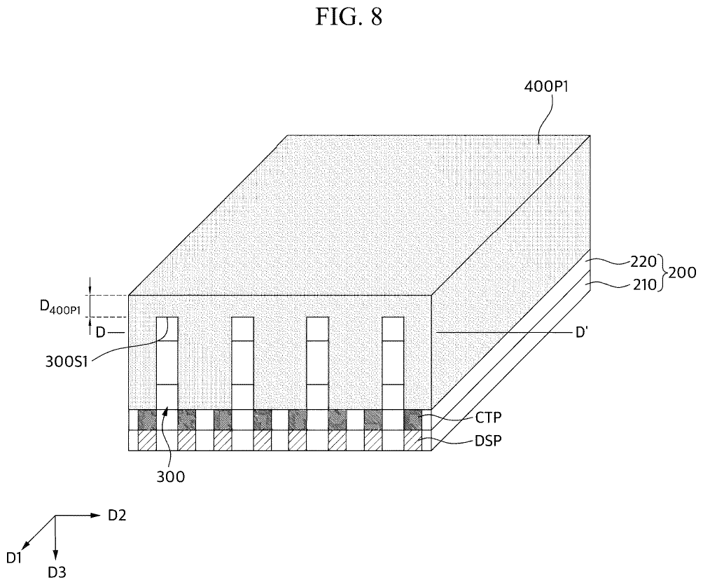

According to some example embodiments, based on the third direction D3, the mold insulation film 300 may include a first surface 300S1 and a second surface 300S2, which is the opposite side of the first surface 300S1 (see FIG. 8). As described above, the first surface 300S1 of the mold insulation film may correspond to the bottom surface 300BS of the mold insulation film in FIG. 1. The second surface 300S2 of the mold insulation film may correspond to the upper surface 300US of the mold insulation film in FIG. 1.

Specifically, the method of manufacturing the semiconductor memory device 10 may include forming the DSPs on the first insulation layer 210, forming CTPs arranged in a grid shape at a position corresponding to the DSP on the second insulation layer 220, and stacking the first insulation layer 210 and the second insulation layer 220 so that the DSPs and the CTPs are in contact. After then, included may be flipping the insulation layer 200 so that the DSPs face the +third direction which is +D3 in FIG. 5. In other words, the insulation layer 200 may be flipped so that the DSP is placed above the CTP in the +third direction which is +D3.

According to some example embodiments, forming the mold insulation film 300 may include that the second surface DSP_S2 of the DSP and the second surface 300S2 of the mold insulation film each face the +third direction which is +D3, based on the third direction D3, and the insulation layer 200 is flipped so that the second surface DSP_S2 of the DSP is placed above the second surface 300S2 of the mold insulation film based on the +third direction, +D3. Further, forming the mold insulation film 300 may include, based on the third direction D3, the second surface DSP_S2 of the DSP and the first surface CTP_S1 of the CTP each facing the +third direction which is +D3, and the insulation layer 200 being flipped so that the second surface DSP_S2 of the DSP is placed above the second surface CTP_S2 of the CTP based on the +third direction, +D3.

In the present disclosure, unless specifically described otherwise, in the method of manufacturing the semiconductor memory device 10, the first surface S1 of an element may face the −third direction which is-D3 in the drawings, and the second surface S2 of an element may face the +third direction which is +D3 in the drawings.

According to some example embodiments, the method of manufacturing the semiconductor memory device 10 may include forming the mold insulation films 300 extending along the first direction D1, spaced apart from each other in the second direction D2 and placed between the DSPs. Specifically, when viewed from the third direction D3, the mold insulation films 300 may be arranged in order not to overlap the DSPs. Meanwhile, as described above, the mold insulation film 300 may be formed into a multi-layer structure. The second surface 300S2 of the mold insulation film may be formed on a first surface 220S1 of the second insulation layer.

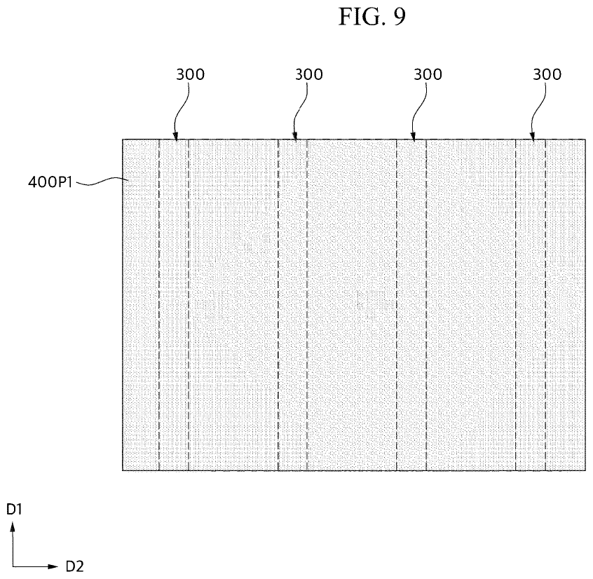

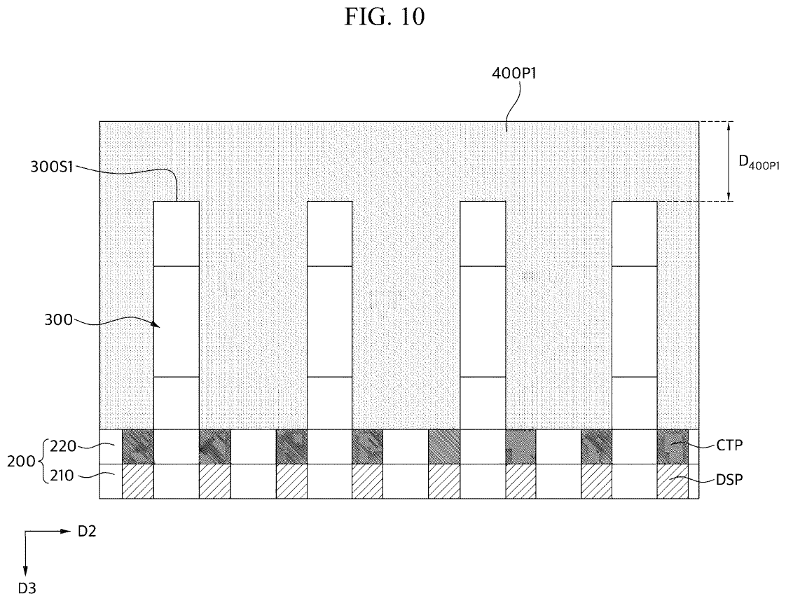

FIG. 8 is a perspective view illustrating the formation of a first pre-channel pattern 400P1 according to some example embodiments. FIG. 9 is a layout view of FIG. 8, and FIG. 10 is a cross-sectional view taken along D-D′ of FIG. 8.

Referring to FIGS. 8 to 10, the method of manufacturing the semiconductor memory device 10 may include forming the first pre-channel pattern 400P1 that covers the mold insulation film 300. The first pre-channel pattern 400P1 may be formed to cover the entire surface of the exposed mold insulation film 300. The first pre-channel pattern 400P1 may cover the first surface 300S1 of the mold insulation film.

The first pre-channel pattern 400P1 may be formed through deposition. For example, chemical vapor deposition (CVD) or atomic layer deposition (ALD) may be used, but the deposition is not limited thereto. The first pre-channel pattern 400P1 may include the oxide semiconductor material included in the channel pattern 400 described above.

When the first pre-channel pattern 400P1 is formed according to some example embodiments, the deposition thickness D400P1 of the first pre-channel pattern 400P1 may be more than ½ of the separation distance between the adjacent mold insulation films 300 based on the second direction D2. The deposition thickness D400P1 of the first pre-channel pattern 400P1 may indicate the distance from the first surface 300S1 of the mold insulation film to the deposition surface of the first pre-channel pattern 400P1 based on the third direction D3.

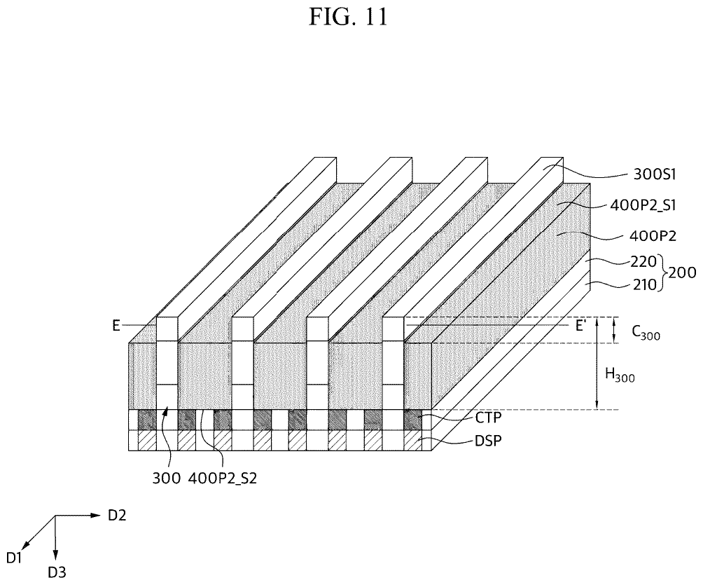

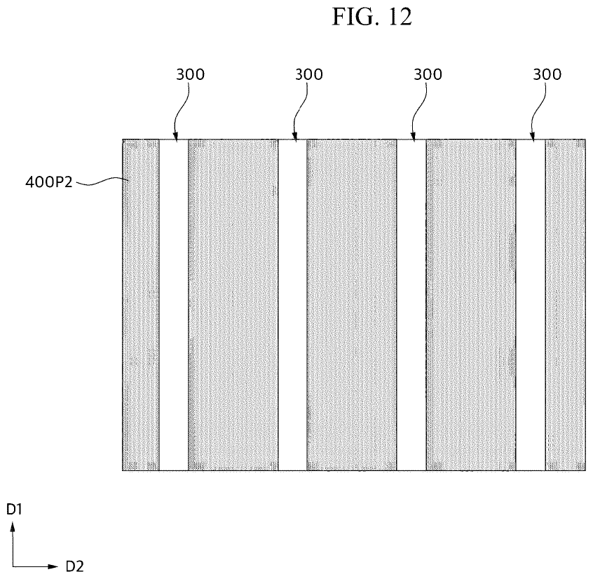

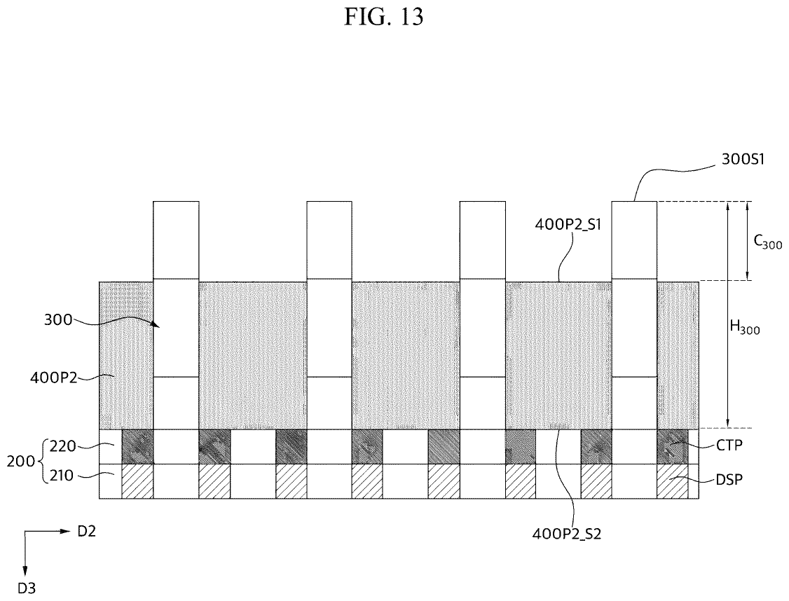

FIG. 11 is a perspective view illustrating some example embodiments where a portion of the first pre-channel pattern 400P1 is removed and a second pre-channel pattern 400P2 is formed. FIG. 12 is a layout view of FIG. 11, and FIG. 13 is a cross-sectional view taken along E-E′ of FIG. 11.

Referring to FIGS. 11 to 13, the method of manufacturing the semiconductor memory device 10 may include forming the second pre-channel pattern 400P2 by removing a portion of the first pre-channel pattern 400P1 to expose a portion of the side surface of the mold insulation film 300 extending in the first direction D1. By removing the first pre-channel pattern 400P1, the first surface 300S1 of the mold insulation film and a portion of the side of the mold insulation film 300 extending in the first direction D1 may be exposed. In other words, by removing the first pre-channel pattern 400P1, the second pre-channel pattern 400P2 may be formed, and based on the third direction D3, a first surface 400P2_S1 of the second pre-channel pattern may be arranged on top in the +third direction which is +D3 compared to the first surface 300S1 of the mold insulation film. In other words, based on the third direction D3, the first surface 400P2_S1 of the second pre-channel pattern may expose the first surface 300S1 of the mold insulation film. The height C₃₀₀ according to the third direction D3 of the mold insulation film 300 exposed by the first pre-channel pattern 400P1 being removed may be ½ or less than ½ of the total height H300 according to the third direction D3 of the mold insulation film 300. Meanwhile, the first surface 400P2_S1 of the second pre-channel pattern may correspond to the bottom surface 400BS of the channel pattern of FIG. 1.

According to some example embodiments, the method of manufacturing the semiconductor memory device 10 may include forming the channel alignment films 800 placed on the sides of the exposed mold insulation film 300 and arranged in a grid shape and spaced at predetermined intervals based on the first direction D1 and the second direction D2.

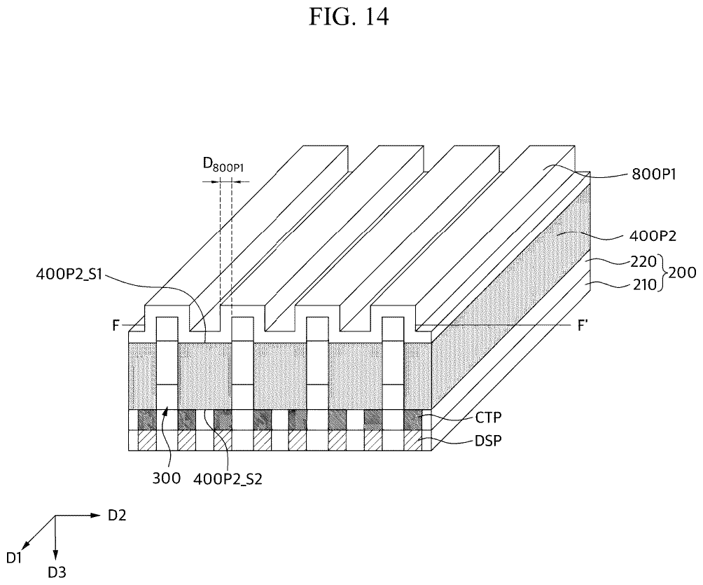

According to some example embodiments, forming the channel alignment film 800 may include forming a first pre channel alignment film 800P1 in FIG. 14 covering the second pre-channel pattern 400P2 and the mold insulation film 300.

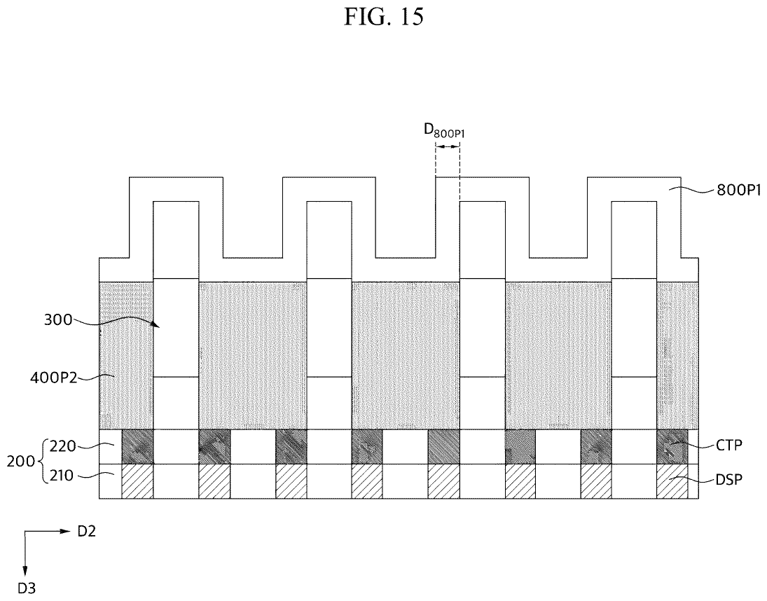

FIG. 14 is a perspective view illustrating the formation of the first pre channel alignment film 800P1 covering the second pre-channel pattern 400P2 and the mold insulation film 300 according to some example embodiments. FIG. 15 is a cross-sectional view taken along line F-F′ of FIG. 14.

Referring to FIGS. 14 and 15, the first pre channel alignment film 800P1 may contain an insulating material and/or a conductive material. The first pre channel alignment film 800P1 may be formed to cover the first surface 400P2_S1 of the second pre-channel pattern and the entire surface of the exposed mold insulation film 300. The first pre channel alignment film 800P1 may be formed through vapor deposition. For example, the CVD or the ALD may be utilized, but the deposition is not limited thereto.

According to some example embodiments, when the first pre channel alignment film 800P1 is formed, the deposition thickness D_{800P1} of the first pre channel alignment film 800P1 may be less than ½ of the separation distance between the adjacent mold insulation films 300 based on the second direction D2. The deposition thickness D_{800P1} of the first pre channel alignment film 800P1 may indicate the width according to the second direction D2 from the side of the mold insulation film 300.

According to some example embodiments, forming the channel alignment film 800 may include removing a portion of the first pre channel alignment film 800P1 to form a second pre channel alignment film 800P2 and removing a portion of the second pre channel alignment film 800P2.

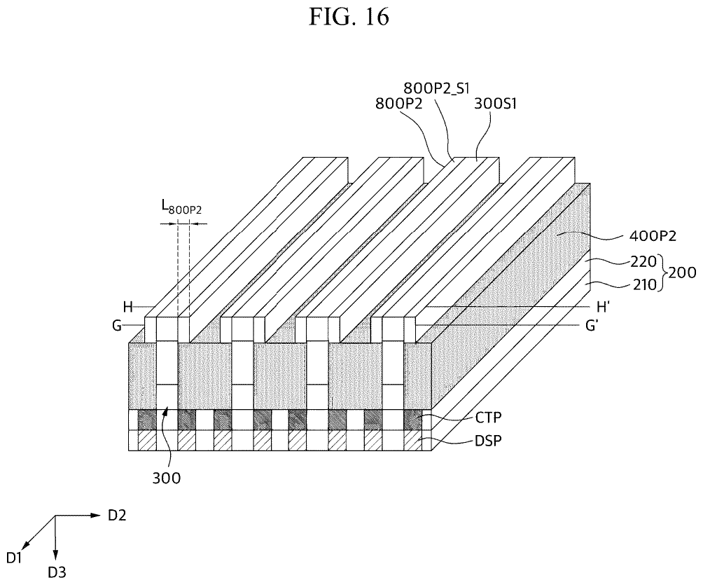

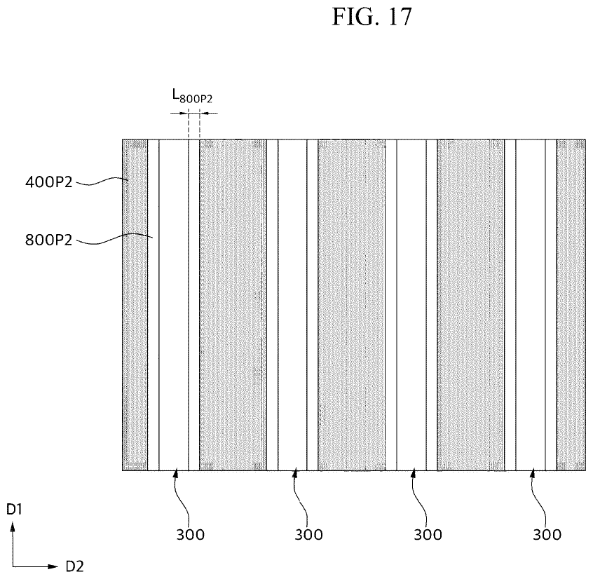

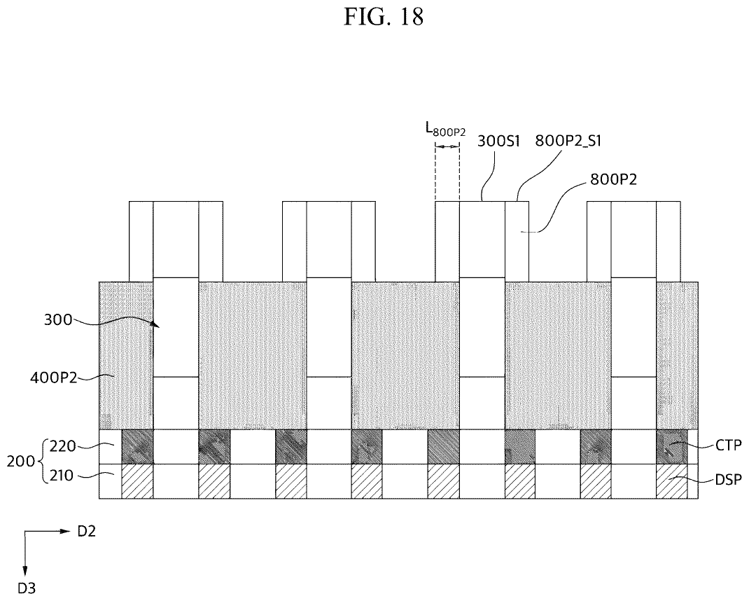

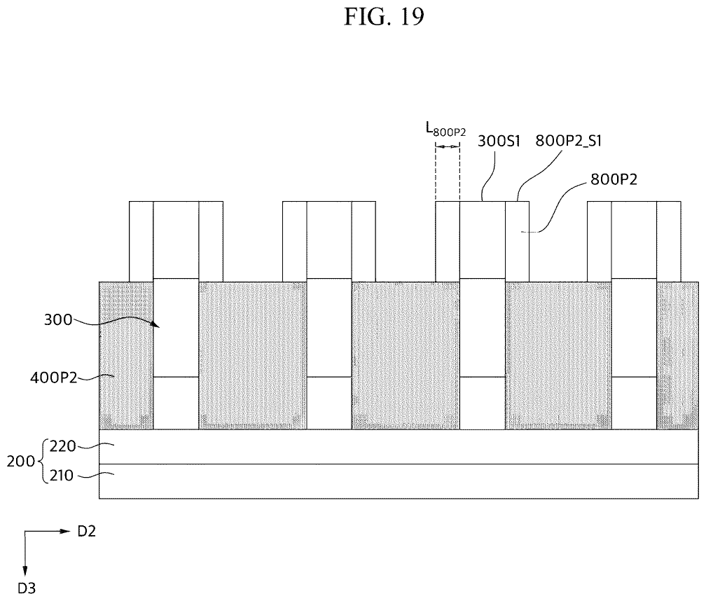

FIG. 16 is a perspective view illustrating the formation of the second pre channel alignment film 800P2 by removing the first pre channel alignment film 800P1 according to some example embodiments. FIG. 17 is a layout view of FIG. 16, and FIG. 18 is a cross-sectional view taken along G-G′ of FIG. 16. FIG. 19 is a cross-sectional view taken along H-H′ in FIG. 16.

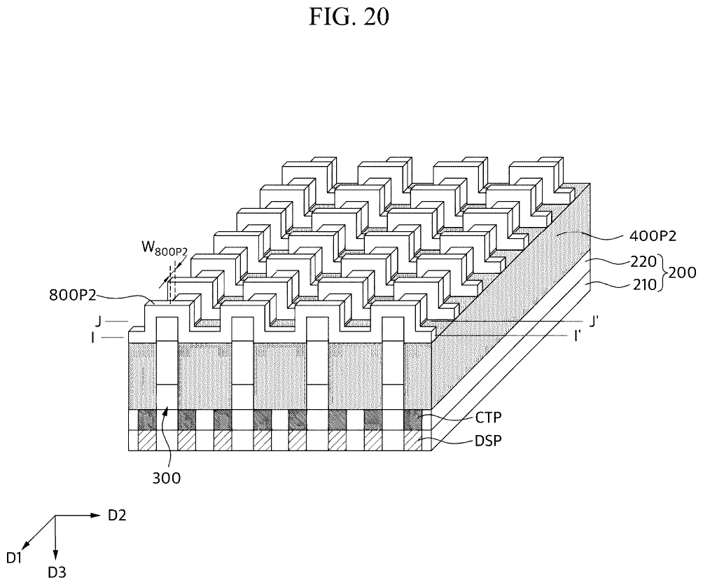

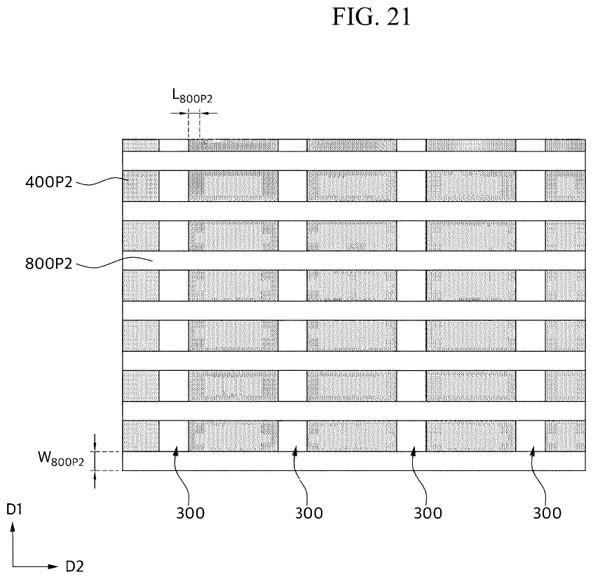

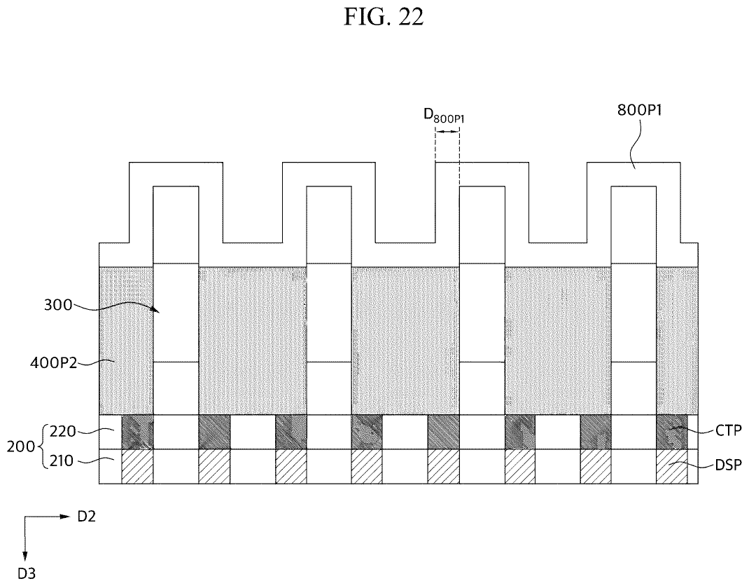

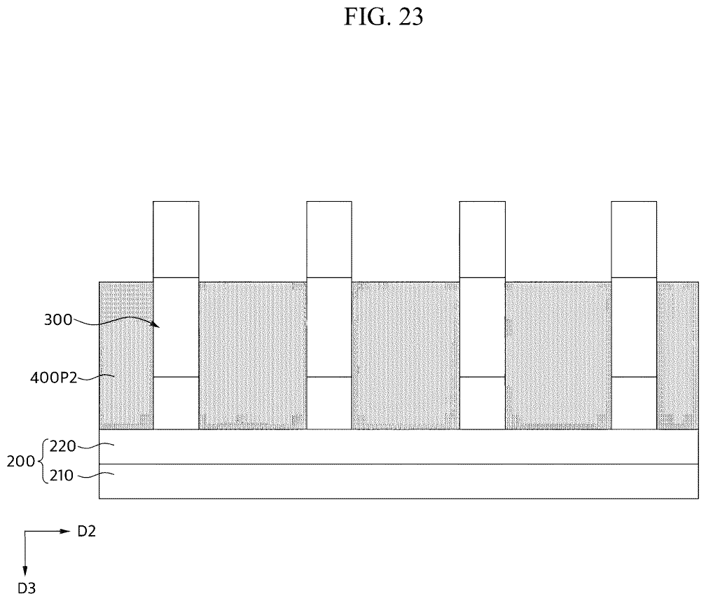

FIG. 20 is a perspective view illustrating the formation of the second pre channel alignment film 800P2 by removing the first pre channel alignment film 800P1 according to some example embodiments. FIG. 21 is a layout view of FIG. 20, and FIG. 22 is a cross-sectional view taken along line I-I′ of FIG. 20. FIG. 23 is a cross-sectional view taken along line J-J′ of FIG. 20.

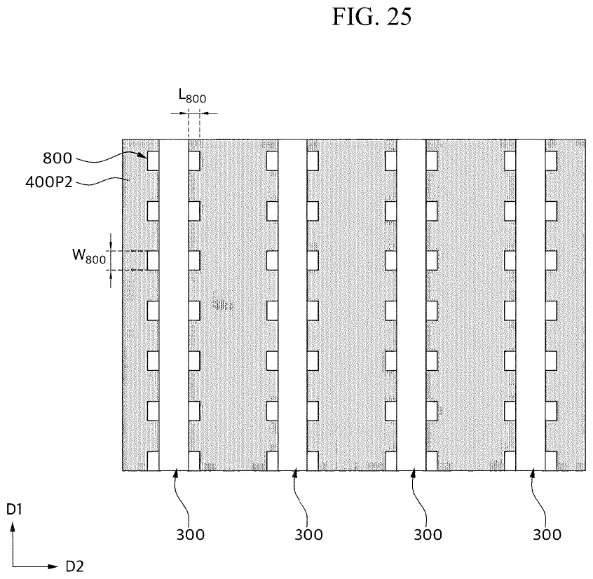

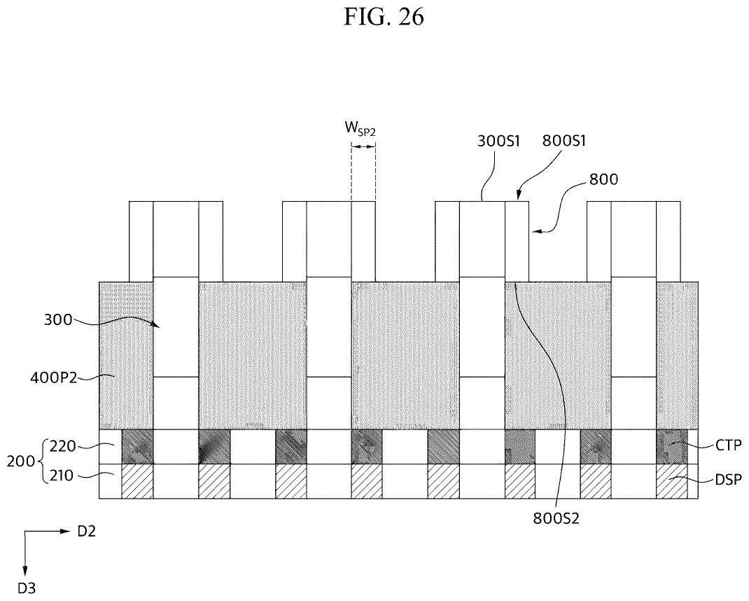

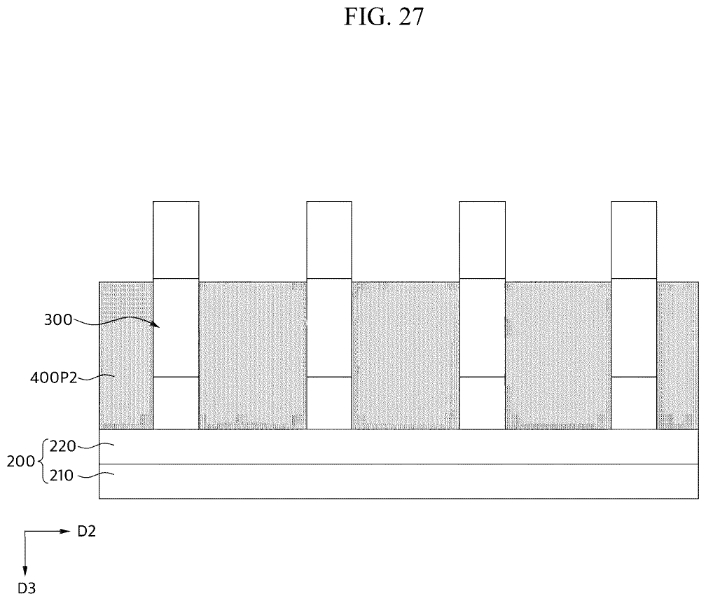

FIG. 24 is a perspective view illustrating forming the channel alignment films 800 that are placed on the side of the mold insulation film 300 exposed by a portion of the second pre channel alignment film 800P2 being removed, and are spaced apart at predetermined intervals based on the first direction D1 and the second direction D2 and arranged in a grid shape. FIG. 25 is a layout view of FIG. 24, and FIG. 26 is a cross-sectional view taken along K-K′ of FIG. 24. FIG. 27 is a cross-sectional view taken along L-L′in FIG. 24.

Referring to FIGS. 16 to 19, removing a portion of the second pre channel alignment film 800P2 after forming the second pre channel alignment film 800P2 may include removing a portion of the first pre channel alignment films 800P1 (see FIG. 14) placed along the side of the mold insulation film 300 and spaced apart from each other based on the second direction D2. For example, in order for the first surface 300S1 of the mold insulation film and a first surface 800P2_S1 of the second pre channel alignment film to be placed on the same plane, a portion of the first pre channel alignment film 800P1 may be removed. Here, the width L_{800P2} for the second direction D2 of the second pre channel alignment film 800P2 may be less than ½ of the separation distance between the adjacent mold insulation films 300 based on the second direction D2.

Further, referring to FIGS. 24 to 27, removing a portion of the second pre channel alignment film 800P2 in FIG. 16 or FIG. 20 after forming the second pre channel alignment film 800P2 in FIG. 16 or FIG. 20 may include removing a portion of the second pre channel alignment films 800P2 in FIG. 16 for being spaced apart from each other based on the first direction D1 and for overlapping the DSP when viewed from the third direction D3.

Meanwhile, referring to FIGS. 20 to 23, removing a portion of the second pre channel alignment film 800P2 after forming the second pre channel alignment film 800P2 may include removing a portion of the first pre channel alignment film 800P1 of FIG. 14 for being extended along the second direction D2 on the mold insulation films 300 and being spaced apart from each other based on the first direction D1. Here, the width W_{800P2} for the first direction D1 of the second pre channel alignment film 800P2 may be less than ½ of the separation distance between the adjacent mold insulation films 300 based on the second direction D2.

Further, referring to FIGS. 24 to 27, removing a portion of the second pre channel alignment film 800P2 in FIG. 16 or 20 after forming the second pre channel alignment film 800P2 in FIG. 16 or 20 may include removing a portion of the second pre channel alignment films 800P2 in FIG. 16 or 20 for being spaced apart from each other based on the second direction D2 and overlapping the DSPs when viewed from the third direction D3.

According to some example embodiments, each of the width W₈₀₀ for the first direction D1 and the width L₈₀₀ for the second direction D2 of the channel alignment film 800 may be less than ½ of the separation distance between the adjacent mold insulation films 300 based on the second direction D2.

According to some example embodiments, by forming the channel alignment film 800, a portion of the second pre channel alignment film 800P2 in FIG. 16 or 20 may be removed, and a first surface 800S1 of the channel alignment film and the first surface 300S1 of the mold insulation film may be placed on the same plane.

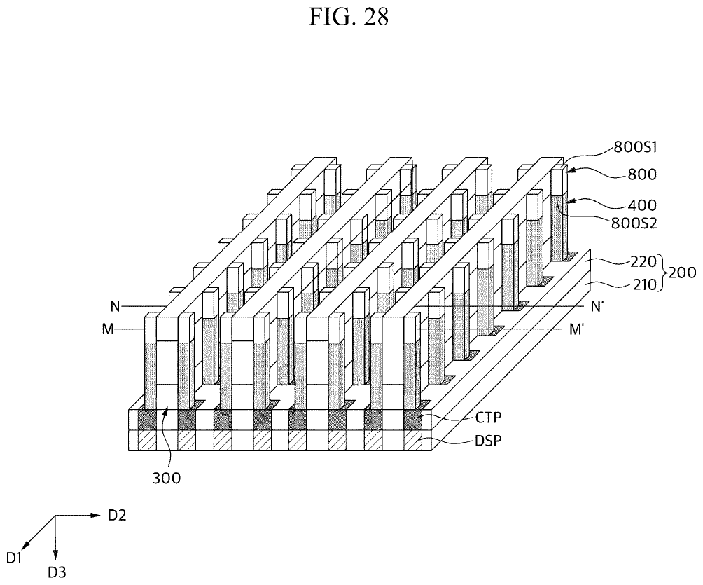

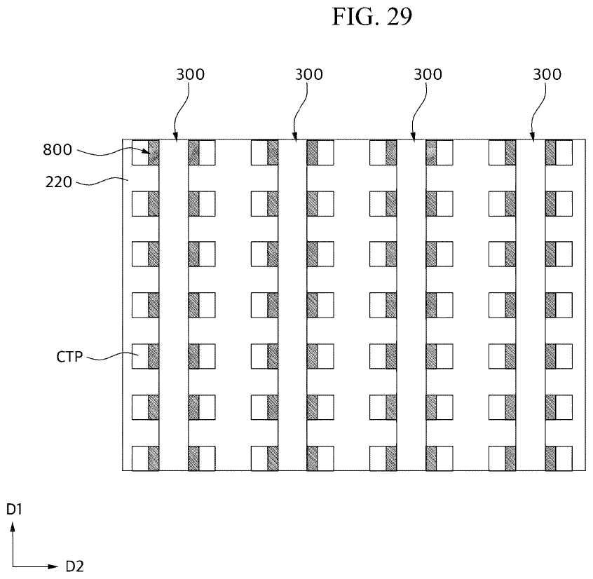

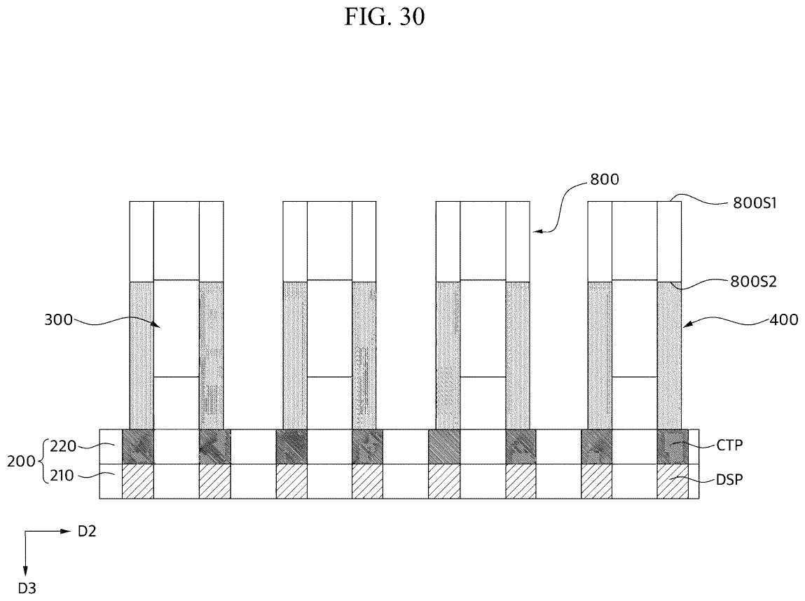

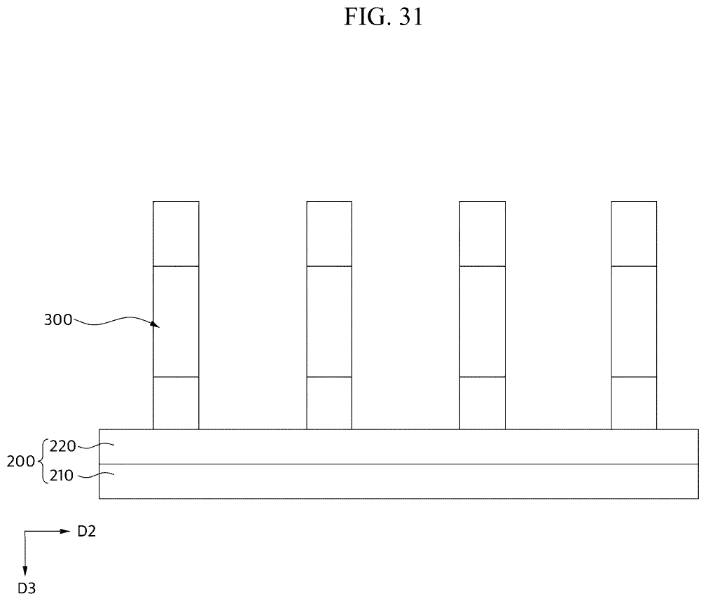

FIG. 28 is a perspective view illustrating formation of the channel pattern 400 disposed on a second surface 800S2 of the channel alignment film 800 (specifically, in order to face the +third direction which is +D3) by patterning the second pre-channel pattern 400P2 in FIG. 24 using the channel alignment film 800. FIG. 29 is a layout view of FIG. 28, and FIG. 30 is a cross-sectional view taken along M-M′ of FIG. 28. FIG. 31 is a cross-sectional view taken along N-N′ of FIG. 28.

According to some example embodiments, the method of manufacturing the semiconductor memory device 10 may include forming the channel pattern 400 disposed on the second surface 800S2 of the channel alignment film 800 (specifically, in the +third direction that is +D3) by patterning the second pre-channel pattern 400P2 in FIG. 24 using the channel alignment film 800. Based on the third direction D3, the channel alignment film 800 may include the first surface 800S1 and the second surface 800S2, which is the surface opposite to the first surface 800S1. As described above, the second surface 800S2 of the channel alignment film 800 may be oriented in the +third direction. The channel pattern 400 may be formed by patterning the second pre-channel pattern 400P2 using the channel alignment film 800 as a mask. The width in the first direction D1 and the width in the second direction D2 of the channel pattern 400 may be equal to the width W₈₀₀ in the first direction D1 and the width L₈₀₀ in the second direction D2 of the channel alignment film 800, respectively.

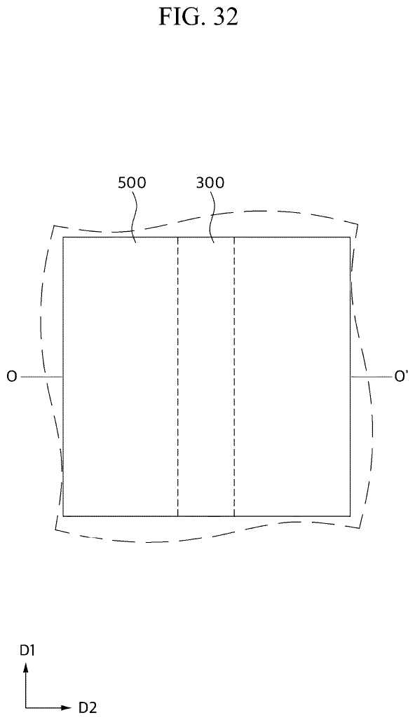

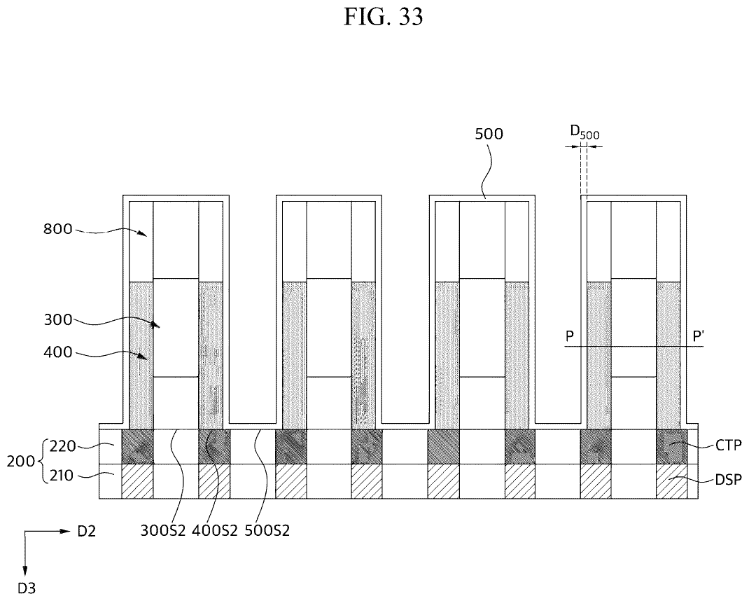

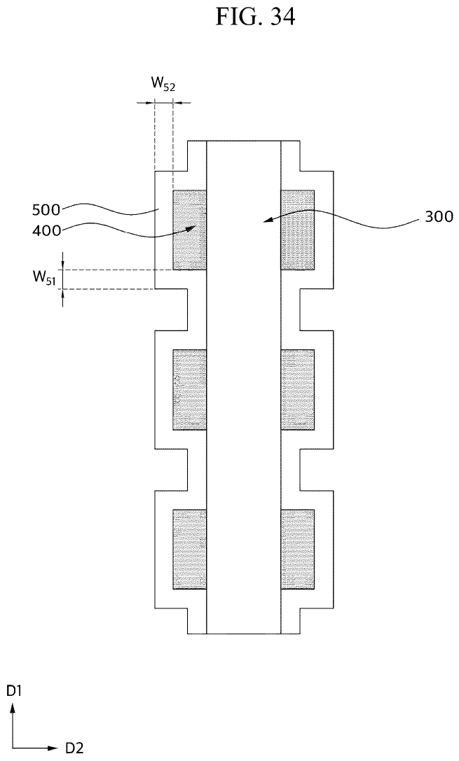

FIG. 32 is a layout diagram illustrating the formation of the gate insulation film 500 covering the mold insulation film 300, the channel pattern 400, and the channel alignment film 800 according to some example embodiments. FIG. 33 is a cross-sectional view taken along O—O′ in FIG. 32. FIG. 34 is a cross-sectional view taken along P-P′ in FIG. 33.

Referring to FIGS. 32 to 34, the method of manufacturing the semiconductor memory device 10 may include forming the gate insulation film 500 covering the mold insulation film 300, the channel pattern 400 and the channel alignment film 800. Forming the gate insulation film 500 may be a single process. The gate insulation film 500 may be formed through vapor deposition. For example, CVD or ALD may be used, but the deposition is not limited thereto. The deposition thickness D₅₀₀ of the gate insulation film 500 may be 5 nm or less.

Referring to FIG. 34, the gate insulation film 500 may include the first width W₅₁ between the channel pattern 400 and the word line WL based on the first direction D1, and the second width W₅₂ between the channel pattern 400 and the word line WL based on the second direction D2, and the first width W₅₁ and the second width W₅₂ may be formed to be the same. Here, “the same” means substantially the same, and may indicate that the difference between the first width W₅₁ and the second width W₅₂ is within 10%. The first width W₅₁ and the second width W₅₂ may be 5 nm or less.

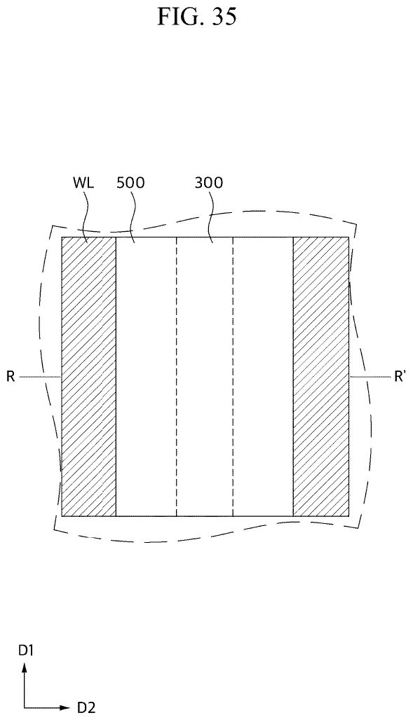

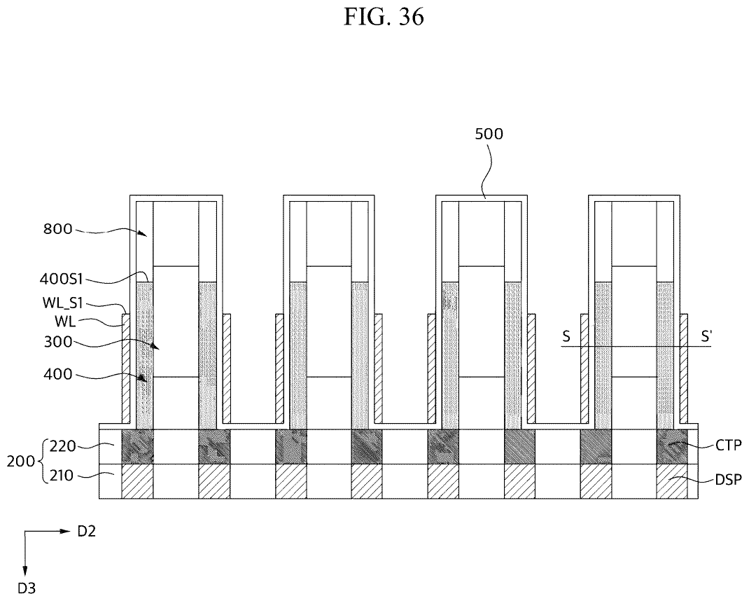

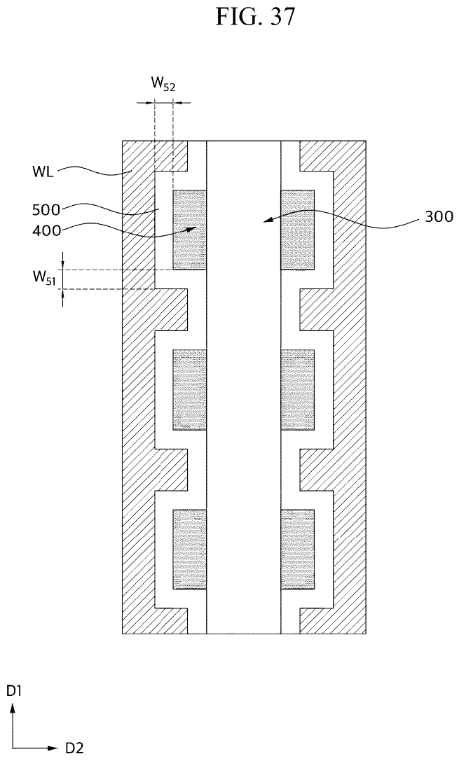

FIG. 35 is a layout diagram illustrating forming the word line WL on the gate insulation film 500 to extend along the first direction D1 between the channel pattern 400 according to some example embodiments. FIG. 36 is a cross-sectional view taken along R-R′ in the case where the channel alignment film 800 includes an insulating material in FIG. 35. FIG. 37 is a cross-sectional view taken along S-S′ of FIG. 36.

Referring to FIGS. 35 to 37, the method of manufacturing the semiconductor memory device 10 may include forming the word line WL on the gate insulation film 500 to extend along the first direction D1 between the channel pattern 400. The word line WL may be formed to be extended according to the first direction D1 while at least a portion of the word line WL overlapping the gate insulation film 500 when viewed from the second direction D2. Further, when viewed from the third direction D3, the word line WL may be formed to overlap a portion of the DSP. Further, the word line WL may be formed to face the CTP with the gate insulation film 500 interposed based on the third direction D3.

Referring to FIGS. 36 and 37, the word line WL may include a first surface WL_S1 facing the −third direction that is-D3 and a second surface that is opposite to first surface WL_S1 and faces the +third direction that is +D3, based on the third direction D3. Further, based on the third direction D3, the channel pattern 400 may include a first surface 400S1 facing the −third direction that is-D3 and a second surface that is opposite to the first surface 400S1 and faces the +third direction, +D3. Based on the −third direction that is-D3, the word line WL may be formed so that the first surface WL_S1 of the word line is placed lower than the first surface 400S1 of the channel pattern.

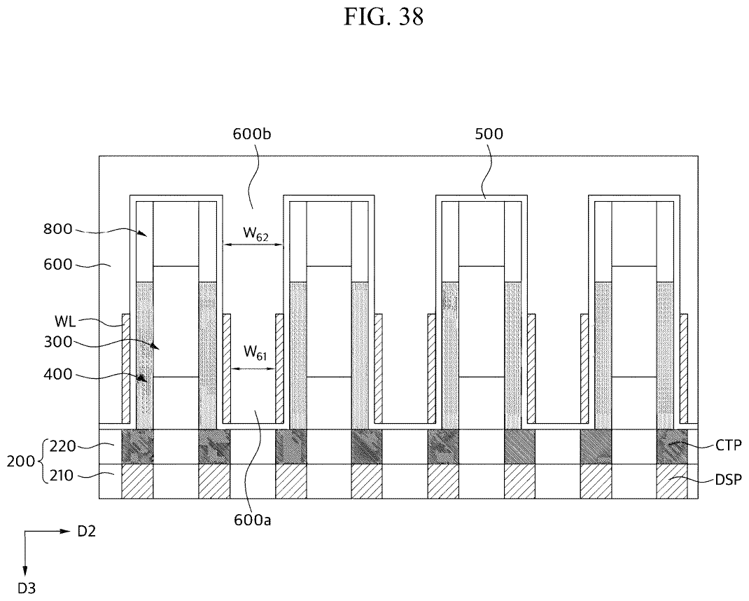

FIGS. 38 to 42 are cross-sectional views illustrating a series of manufacturing processes after forming the word line WL when the channel alignment film 800 includes an insulating material.

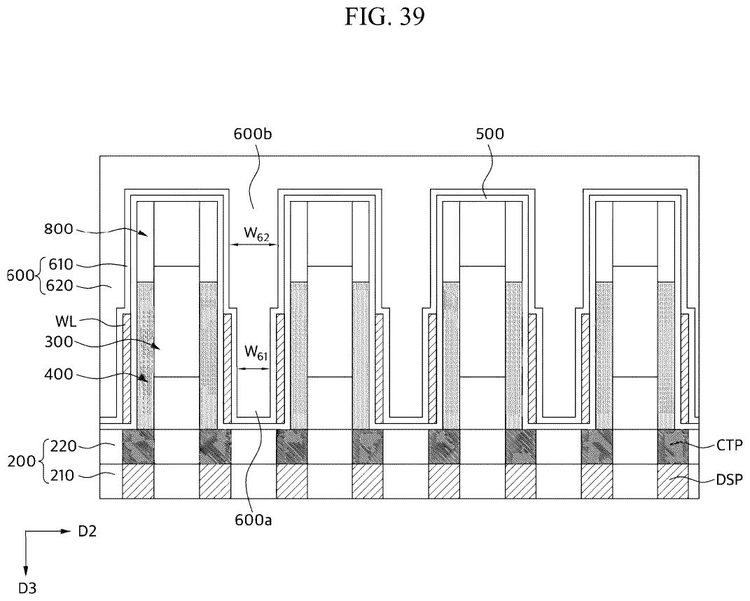

According to some example embodiments, the method of manufacturing the semiconductor memory device 10 may include that the channel alignment film 800 includes an insulating material, and the gate capping film 600 covering the gate insulation film 500 and the word line WL is formed. Referring to FIG. 38, the gate capping film 600 may be formed in order to cover the gate insulation film 500 and the word line WL and fill the spaces between the mold insulation films 300 spaced apart. The gate capping film 600 may include a single layer. Referring to FIG. 39, the gate capping film 600 may include multilayers. For example, forming the gate capping film 600 may include forming the liner film 610 to contact and cover the gate insulation film 500 and the word line WL, and forming the filling film 620 that fills the gap between the mold insulation films 300 spaced apart. The filling film 620 may be formed to be placed on the liner film 610.

According to some example embodiments, with regard to forming the gate capping film 600, on the cross section cut along the first direction D1, the gate capping film 600 may be formed to include the first part 600a and the second part 600b excluding the first part 600a overlapping the word line WL in the first direction D1 and the second direction D2. Based on the +third direction that is +D3, the second part 600b may be placed lower than the first part 600a. The gate capping film 600 may be formed so that the width W₆₂ of the second part 600b is larger than the width W₆₁ of the first part 600a, based on the second direction D2.

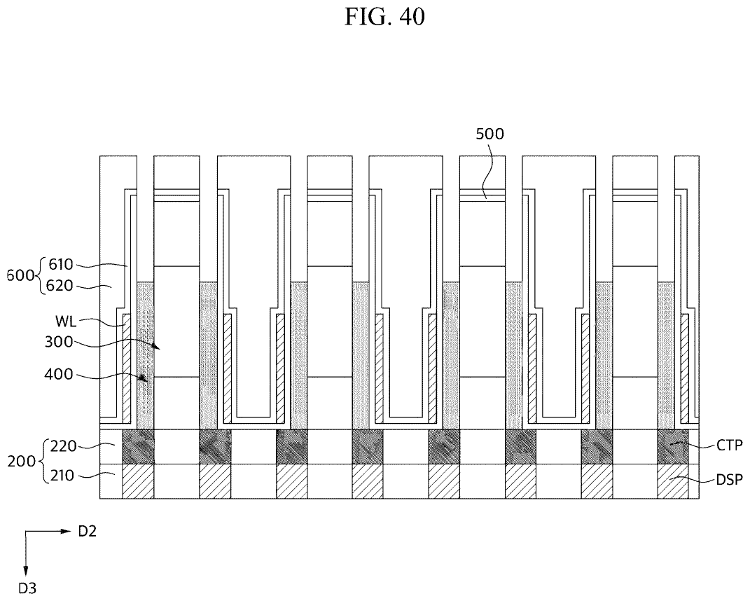

Referring to FIG. 40, the method of manufacturing the semiconductor memory device 10 may include removing the channel alignment film 800 in FIG. 39. Referring to FIG. 40, the channel alignment film 800 in FIG. 39 may be removed in order for the channel pattern 400 to be exposed based on the third direction D3. Removing the channel alignment film 800 in FIG. 39 may include removing the gate capping film 600 and the gate insulation film 500 that overlap the channel alignment film 800 in FIG. 39 when viewed from the third direction D3. Removing the channel alignment film 800 when the gate capping film 600 includes the liner film 610 and the filling film 620 may include removing the liner film 610 and the filling film 620 that overlap the channel alignment film 800 in FIG. 39 when viewed from the third direction D3.

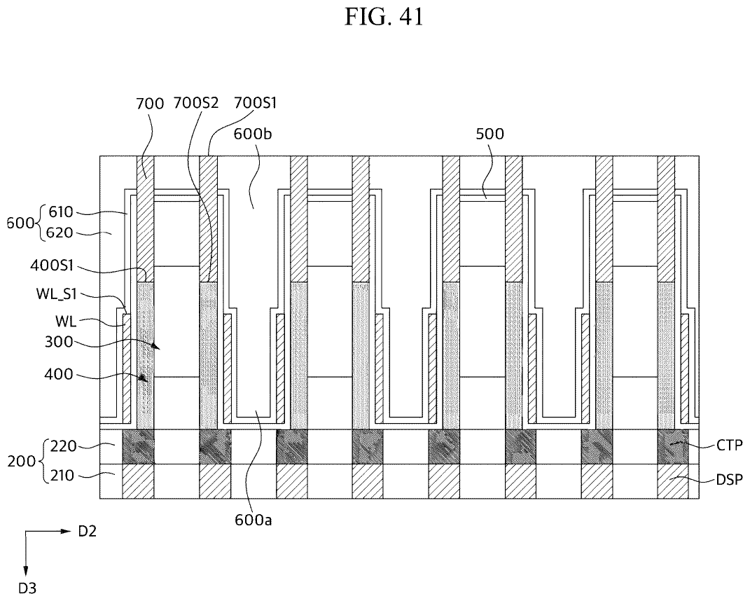

Referring to FIG. 41, the method of manufacturing the semiconductor memory device 10 may include forming the connection plug 700 in the area where the channel alignment film 800 was removed so that the connection plug 700 completely or partially overlaps the channel pattern 400 when viewed from the third direction D3. The connection plug 700 may be formed so that a second surface 700S2 of the connection plug and the first surface 400S1 of the channel pattern are on the same plane.

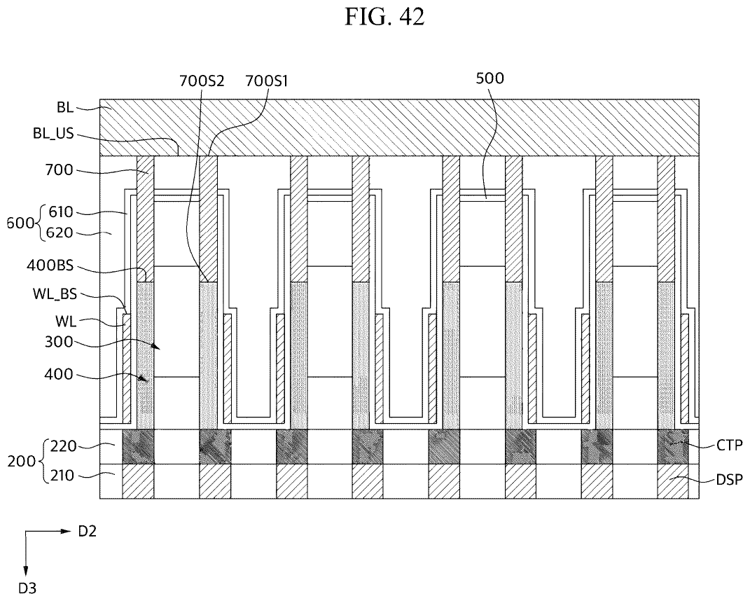

Referring to FIG. 42, the method of manufacturing the semiconductor memory device 10 may include forming the bit line BL that is placed on the gate capping film 600 and that extends in the second direction D2 and is connected to the connection plug 700. The bit line BL may be formed so that the first surface 300S1 of the mold insulation film and a second surface BL_S2 of the bit line are spaced apart based on the third direction D3.

Meanwhile, according to some example embodiments, in the method of manufacturing the semiconductor memory device 10, the second part 600b may be placed closer to the second surface BL_S2 of the bit line than the first part 600a. The bit line BL may include a first surface BL_S1 facing the −third direction that is-D3 and the second surface BL_S2 that is opposite to the first surface BL_S1 and faces the +third direction that is +D3, based on the third direction D3.

According to some example embodiments, the method of manufacturing the semiconductor memory device 10 may include flipping back the semiconductor memory device 10 that is in the form of a semi-finished product manufactured through the above-mentioned series of processes. The method may include connecting the substrate 100 and the peripheral gate structure PRG, such as what is illustrated in FIG. 1 with respect to the semiconductor memory device 10.

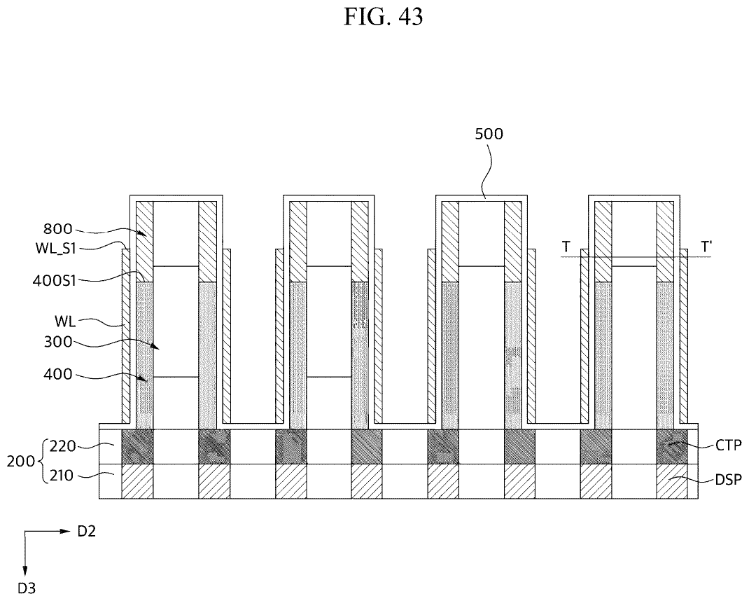

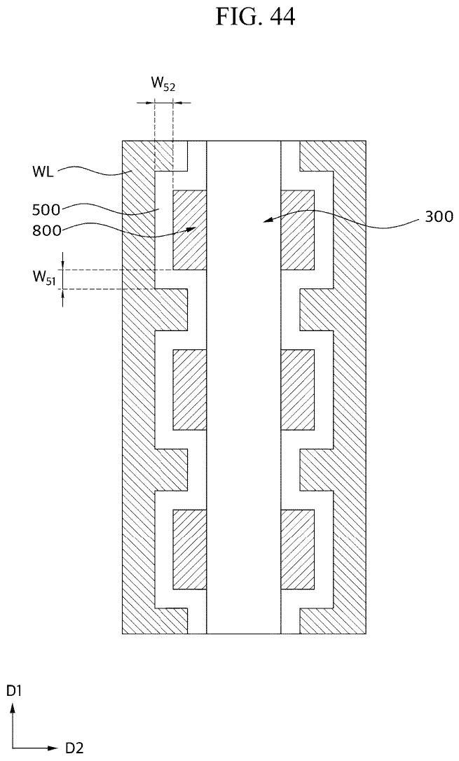

FIG. 43 is a cross-sectional view taken along R-R′ in the case where the channel alignment film 800 includes a conductive material in FIG. 35. FIG. 44 is a cross-sectional view taken along T-T′ in FIG. 43. For the convenience of explanation, the description will focus on differences from those described with reference to FIGS. 36 and 37.

According to another example embodiment, based on the −third direction-D3, the word line WL may be formed so that the first surface WL_S1 of the word line is on the same plane as the first surface 400S1 of the channel pattern or is above the first surface 400S1 of the channel pattern. Referring to FIGS. 43 and 44, based on the −third direction, −D3, the word line WL may be formed so that the first surface WL_S1 of the word line is higher than the first surface 400S1 of the channel pattern.

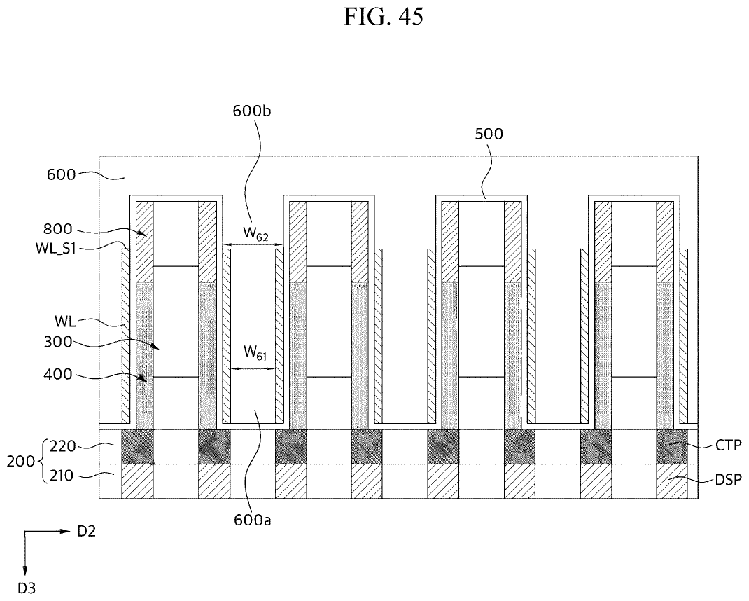

FIGS. 45 to 48 are cross-sectional views illustrating a series of manufacturing processes after forming the word line WL when the channel alignment film 800 contains a metal material.

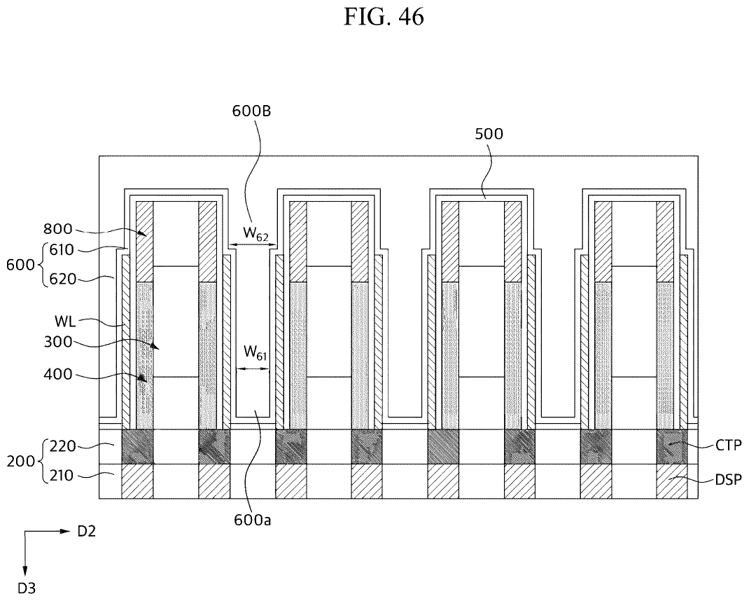

According to some example embodiments, the method of manufacturing the semiconductor memory device 10 may include that the channel alignment film 800 includes a conductive material and the gate capping film 600 it formed that covers the gate insulation film 500 and the word line WL. Referring to FIG. 45, the gate capping film 600 may be formed to cover the gate insulation film 500 and the word line WL and fill the gap between the mold insulation films 300 spaced apart. The gate capping film 600 may be a single layer. Referring to FIG. 46, the gate capping film 600 may be a multi-layer. For example, forming the gate capping film 600 may include forming the liner film 610 to contact and cover the gate insulation film 500 and the word line WL, and forming the filling film 620 that fills the gap between the mold insulation films 300 spaced apart. The filling film 620 may be formed to be placed on the liner film 610.

According to some example embodiments, with respect to forming the gate capping film 600, on the cross section cut along the first direction D1, the gate capping film 600 may be formed to include the first part 600a overlapping the word line WL in the first direction D1 and the second direction D2, and the second part 600b excluding the first part 600a. Based on the +third direction which is +D3, the second part 600b may be placed lower than the first part 600a. Based on the second direction D2, the gate capping film 600 may be formed so that the width W₆₂ of the second part 600b is larger than the width W₆₁ of the first part 600a.

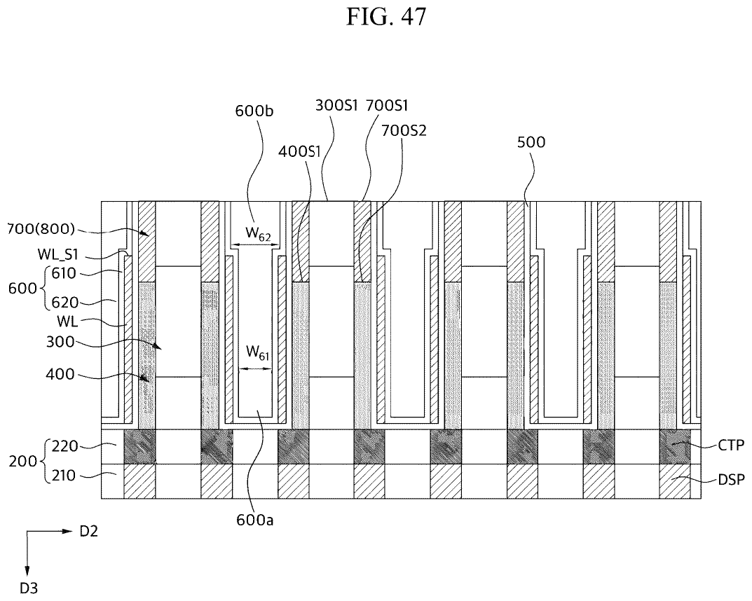

Referring to FIG. 47, the method of manufacturing the semiconductor memory device 10 may include removing a portion of the gate insulation film 500 and the gate capping film 600 to expose the channel alignment films 800 in FIG. 46 based on the third direction D3. If the gate capping film 600 includes the liner film 610 and the filling film 620, removing the liner film 610 and the filling film 620 to expose the channel alignment film 800 in FIG. 46 may be included. Here, since the channel alignment film 800 contains conductive material, the channel alignment film 800 itself may be the connection plug 700 in FIG. 42. In other words, if the channel alignment film 800 in FIG. 46 includes a conductive material, without performing the process of removing the channel alignment film 800 and forming the separate connection plug 700 in FIG. 42, the bit line BL, which will be described later, and channel pattern 400 may be connected. Removing a portion of the gate insulation film 500 and the gate capping film 600 may include removing a portion of the gate insulation film 500 and the gate capping film 600 in order for a first surface 700S1 of the connection plug 700 (that is, the channel alignment film) and the first surface 300S1 of the mold insulation film to be on the same plane. The gate insulation film 500 and the gate capping film 600 may be removed in parallel along the third direction D3.

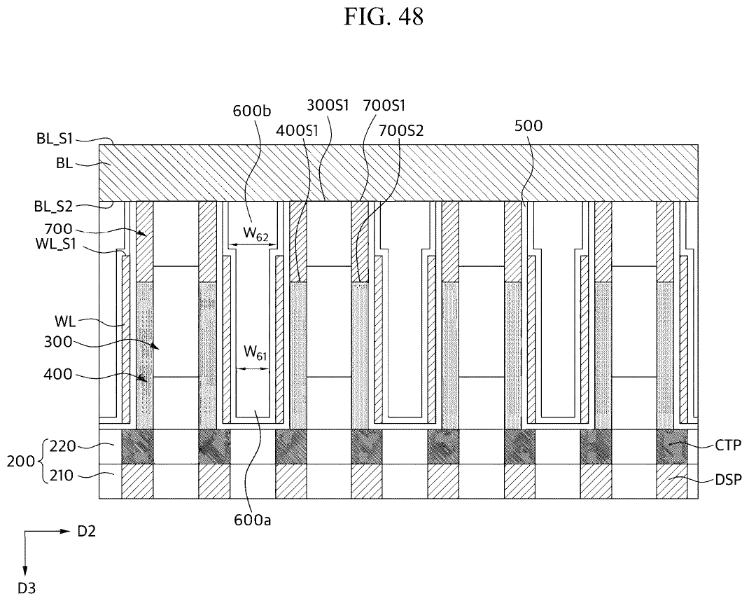

Referring to FIG. 48, the method of manufacturing the semiconductor memory device 10 may include forming the bit line BL that is placed on the gate capping film 600, extending in the second direction D2 and connected to the channel alignment film 800 in FIG. 46. As described above, since the channel alignment film 800 in FIG. 46 contains a conductive material, the channel alignment film 800 itself may be the connection plug 700. Based on the third direction D3, the bit line BL may be formed so that the first surface 300S1 of the mold insulation film and the second surface BL_S2 of the bit line are on the same plane.

Meanwhile, according to some example embodiments, in the method of manufacturing the semiconductor memory device 10, based on the third direction D3, the second part 600b may be placed closer to the second surface BL_S2 of the bit line than the first part 600a. Based on the third direction D3, the bit line BL may include the first surface BL_S1 facing the −third direction which is-D3, and the second surface BL_S2 that is opposite to the first surface BL_S1 and faces the +third direction that is +D3.

According to some example embodiments, the method of manufacturing the semiconductor memory device 10 may include flipping back the semiconductor memory device 10 that is in the form of a semi-finished product manufactured through the above-mentioned series of processes. The method may include connecting the substrate 100 and the peripheral gate structure PRG, such as what is illustrated in FIG. 3 with respect to the semiconductor memory device 10.

The example embodiments of the present disclosure are described with reference to the attached drawings. However, the present disclosure is not limited to the example embodiments, and the present disclosure can be manufactured in various other forms, and a person skilled in the art to which the present disclosure pertains will understand that the present disclosure can be implemented in other specific forms without changing its technical idea or essential features. Therefore, the example embodiments described above should be understood in all respects as illustrative and not limiting.

What is claimed is:

1. A semiconductor memory device comprising:
mold insulation films extending along a first direction and spaced apart from each other based on a second direction intersecting the first direction;
a channel pattern protruding from the mold insulation films in the second direction;
a gate insulation film covering at least a portion of the mold insulation films and the channel pattern;
a word line on the gate insulation film; and
a gate capping film extending along the first direction and covering at least a portion of the gate insulation film and the word line,
wherein the gate capping film includes
a first part overlapping the word line in the first direction and the second direction in a cross-sectional view cut along the first direction, and
a second part is placed below the first part along a vertical direction that intersects the first direction and the second direction,
wherein, a width of the second part in the second direction is greater than a width of the first part in the second direction,
wherein the gate insulation film has a first width between the channel pattern and the word line based on the first direction and a second width between the channel pattern and the word line based on the second direction, and
wherein the first width and the second width are substantially the same.

2. The semiconductor memory device of claim 1, wherein the channel pattern comprises an oxide semiconductor material.

3. The semiconductor memory device of claim 2, wherein the first width and the second width are each 5 nanometers (nm) or less.

4. The semiconductor memory device of claim 1, wherein the gate insulation film is a single layer.

5. The semiconductor memory device of claim 1, wherein,
based on the vertical direction that intersects the first direction and the second direction, an upper surface of the mold insulation films, an upper surface of the channel pattern and an upper surface of the gate insulation film are on a same plane.

6. The semiconductor memory device of claim 1, further comprising:
a bit line extending in the second direction, and below the mold insulation films in the vertical direction,
wherein a bottom surface of the channel pattern is spaced apart from an upper surface of the bit line in the vertical direction.

7. The semiconductor memory device of claim 6, wherein a bottom surface of the word line is spaced apart from the upper surface of the bit line in the vertical direction.

8. The semiconductor memory device of claim 6, further comprising:
a connection plug electrically connecting the bit line and the channel pattern,
wherein an upper surface of the connection plug is above a bottom surface of the mold insulation films in the vertical direction.

9. The semiconductor memory device of claim 8, wherein the upper surface of the connection plug is lower than a bottom surface of the word line in the vertical direction.

10. The semiconductor memory device of claim 8, wherein the bottom surface of the mold insulation films is spaced part from the upper surface of the bit line in the vertical direction.

11. The semiconductor memory device of claim 8, wherein the upper surface of the connection plug is at a same plane or above a bottom surface of the word line in the vertical direction.

12. The semiconductor memory device of claim 8, wherein the bottom surface of the mold insulation films and the upper surface of the bit line are on an identical plane in the vertical direction.

13. The semiconductor memory device of claim 1, further comprising:
data stored patterns (DSPs) on top of the channel pattern and the gate insulation film in the vertical direction.

14. The semiconductor memory device of claim 1, wherein the gate capping film comprises
a liner film in contact with the gate insulation film and the word line, and
a filling film filling the space between the mold insulation films.

15. A method of manufacturing a semiconductor memory device, the method comprising:
forming data stored patterns (DSPs) in a grid shape such that the DSPs are each spaced part at a first predetermined interval in a first direction and a second direction intersecting with the first direction;
forming mold insulation films extending along the first direction and spaced apart from each other based on the second direction and placed between the DSPs;
forming a first pre-channel pattern covering the mold insulation films;
forming a second pre-channel pattern by removing a portion of the first pre-channel pattern such that a portion of a side of the mold insulation films extending along the first direction is exposed;
forming channel alignment films on the exposed side of the mold insulation films such that the channel alignment films are in a grid shape and spaced apart from each other at a second predetermined interval in the first direction and the second direction;
forming a channel pattern on top of the channel alignment films by patterning the second pre-channel pattern using the channel alignment films;
forming a gate insulation film such that the gate insulation film covers the mold insulation films, the channel pattern and the channel alignment films; and
forming a word line on the gate insulation film such that the word line extends along the first direction between the channel pattern.

16. The method of claim 15, wherein forming the channel alignment films comprises
forming a first pre channel alignment film covering the second pre-channel pattern and the mold insulation films, and
removing a portion of the first pre channel alignment film to form a second pre channel alignment film and then removing a portion of the second pre channel alignment film, and
wherein forming the second pre channel alignment film and removing the portion of the second pre channel alignment film includes at least one of:
removing a portion of the first pre channel alignment film such that the first pre channel alignment films are disposed along a side of the mold insulation films and spaced apart from each other in the second direction, and
removing a portion of the second pre channel alignment film such that the second pre channel alignment films are spaced apart from each other based on the first direction and overlap with the DSPs when viewed in a vertical direction that intersects the first direction and the second direction; or
removing a portion of the first pre channel alignment film such that the first pre channel alignment film extends along the second direction on the mold insulation films and the second pre-channel pattern and is spaced apart from each other based on the first direction, and
removing a portion of the second pre channel alignment film such that the second pre channel alignment film is spaced apart from each other based on the second direction and overlap the DSPs when viewed from thevertical direction.

17. The method of claim 15, further comprising:
forming a gate capping film that covers the gate insulation film and the word line;
removing at least a portion of the channel alignment films;
forming a connection plug in an area where the channel alignment films are removed such that the connection plug overlaps the channel pattern when viewed in a vertical direction that intersects the first direction and the second direction; and
forming a bit line on the gate capping film, extending in the second direction, and connected to the connection plug,
wherein the channel alignment films comprise an insulating material.

18. The method of claim 15, further comprising:
forming the gate capping film such that the gate capping film covers the gate insulation film and the word line;
removing a portion of the gate insulation film and the gate capping film in order for the channel alignment films to be exposed in a vertical direction that intersects the first direction and the second direction; and
forming a bit line on the gate capping film, extending in the second direction and connected to the channel alignment films,
wherein the channel alignment films comprise a conductive material.

19. The method of claim 15, wherein the DSPs includes a first surface and a second surface that is an opposite surface of the first surface, and the mold insulation films includes a first surface and a second surface that is an opposite surface of the first surface, and
wherein the method further comprises:
flipping the semiconductor memory device in order for each of the second surface of the DSPs and the second surface of the mold insulation films to face upwards in a vertical direction that intersects the first direction and the second direction, and in order for the second surface of the DSPs to be placed above the second surface of the mold insulation films based on the vertical direction.

20. A semiconductor memory device comprising:
mold insulation films extending along a first direction and spaced apart from each other based on a second direction intersecting the first direction;
a channel pattern protruding from the mold insulation films in the second direction;
a gate insulation film covering at least a portion of the mold insulation films and the channel pattern;
a word line on the gate insulation film;
a gate capping film extending along the first direction and covering at least a portion of the gate insulation film and the word line;
a bit line at a bottom of the mold insulation films and extending in the second direction based on a vertical direction that intersects the first direction and the second direction;
a connection plug connecting the bit line and the channel pattern; and
data stored patterns (DSPs) on top of the channel pattern and the gate insulation film,
wherein the gate capping film includes
a first part overlapping the word line in the first direction and the second direction in a cross-sectional view cut along the first direction, and
a second part is placed below the first part along the vertical direction, the second part is placed adjacent to an upper surface of the bit line than the first part in the vertical direction,
wherein a width of the second part in the second direction is greater than a width of the first part in the second direction,
wherein the gate insulation film has a first width between the channel pattern and the word line in the first direction and a second width between the channel pattern and the word line in the second direction, and the first width and the second width are substantially the same, and
wherein an upper surface of the mold insulation films, an upper surface of the channel pattern and an upper surface of the gate insulation film are on an same plane, the gate capping film is between a bottom surface of the channel pattern and the upper surface of the bit line, and the connection plug has an upper surface that is above a bottom surface of the mold insulation films.
